(19) United States
(12) Patent Application Publication
(10) Pub. No.: US 2024/0279402 A1
(43) Pub. Date: Aug. 22, 2024

(54) COMPOSITIONS CONTAINING POLYORGANOSILOXANES HAVING POLYPHENYLENE ETHER GROUPS

(71) Applicant: WACKER CHEMIE AG, Munich (DE)

(72) Inventor: Frank SANDMEYER, Burgkirchen (DE)

(73) Assignee: WACKER CHEMIE AG, Munich (DE)

(21) Appl. No.: 18/567,496

(22) PCT Filed: Jun. 7, 2021
(86) PCT No.: PCT/EP2021/065191

§ 371 Date: Dec. 6, 2023

(51) Int. Cl. C08G 77/46; C08G 65/48; H05K 1/03

(52) U.S. Cl. CPC C08G 77/46; C08G 65/485; H05K 1/0366

(57) ABSTRACT

A process for producing compositions includes selecting compounds from hydroxy-terminated homopolymeric or copolymeric polyphenylene ethers and phenols and reacting such compounds with chlorosilane of formula (I), R¹ₐR²_{b}SiCl_{4-a-b} (I), alone or in admixture with disiloxane of formula (IV), [R¹_{(3-b)}R²_{b}Si]₂O (IV), in the presence of water and solvent.

The present invention relates to a process for producing compositions, wherein polyphenylene ether or phenols are reacted with chlorosilane alone or in admixture with disiloxane, to the compositions obtainable by the process and to the use thereof.

The ongoing development of high-frequency technology for wireless communication is accompanied by an increasing demand for materials suitable for its realization. This applies to all sectors of materials such as copper foil, binders, glass fibers etc. In the case of the binders the epoxy resins classically used for production of copper-clad laminates or for printed circuit board manufacture are no longer usable on account of excessively high dielectric loss factors. Polytetrafluoroethylene, which has a very low dielectric loss factor and is thus well-suited in this aspect for high-frequency applications, has other disadvantages, in particular poor processability and poor adhesion properties, which make it is desirable to find an alternative. Polyphenylene ethers are currently intensively utilized as binders for this field of application since they combine low dielectric loss factors with good mechanical and thermal properties and water repellency.

Polyorgansiloxanes have excellent heat resistance, weathering resistance and hydrophobicity, are flame retardant and have low dielectric loss factors.

These property profiles qualify both the polyphenylene ethers and the polyorganosiloxanes for use as binders for production of high-frequency copper-clad laminates and components, such as printed circuit boards and antennae. It is therefore obvious to combine the positive properties of these two material classes to symbiotically increase their performance. Corresponding experiments are already documented in the prior art.

### PRIOR ART

U.S. Pat. No. 6,258,881 describes polyphenylene ether compositions which are made flame retardant through addition of silicones and can dispense with the addition of flame retardants. The compositions are physical mixtures of polyphenylene ethers and optionally further organic polymer components and the silicone building blocks. A good compatibility of the two preparation components is essential to achieve the desired effect of flame retardancy. This is only achieved with a certain ratio of Si—C-bonded methyl groups and phenyl groups in the silicone building block. The use of pure methyl resins is just as out of the question here as that of pure phenyl resins. In addition to flame retardancy the ratio of the silicon-bonded methyl and phenyl groups also determines further properties of the preparation, such as the mechanical properties expressed via impact strength. In the compositions the silicone component forms the disperse phase in the continuous phase of the polyphenylene ether. U.S. Pat. No. 6,258,881 teaches that only certain particle sizes of the dispersed silicone particles in the polyphenylene ether phase allow adequate flame resistance. In case of excessively large particle sizes, further negative side effects such as delamination effects may occur. The silicone components which achieve the inventive effect according to U.S. Pat. No. 6,258,881 are preferably solids, since liquid silicone components may not be sufficiently dispersible in the polyphenylene ethers.

Further examples of the use of compositions of physical mixtures of polyphenylene ethers with polyorganosiloxanes for improving specific properties may be found in U.S. Pat. No. 3,737,479 (improving impact strength), U.S. Pat. No. 5,834,585 (mixtures of chemically curable polyphenylene ethers having improved processability), US 2004/0138355 (improving flame retardancy through blends with closed and partially open silsesquioxane cage structures), U.S. Pat. No. 3,960,985 (improving thermal stability of mixtures of polyphenylene ethers with alkenylaromatic polymers by addition of small amounts of internally Si—H-functional polydimethylsiloxanes).

U.S. Pat. No. 5,357,022 teaches flame retardant silicone-polyphenylene ether block copolymers obtained by oxidative coupling of phenol-terminated polydiorganosiloxane macromers and alkyl- or aryl-substituted phenols. The method is limited to at most difunctionalized polydiorganosiloxanes macromers with terminal arrangement of the phenol functions. Obtained here are unreactive thermoplastic block copolymers which no longer have functional groups for further chemical crosslinking.

U.S. Pat. No. 4,814,392 teaches production of silicone-polyphenylene ether block copolymers by reaction of alpha-omega amine-terminated polydiorganosiloxanes with anhydride-functional polyarylene ethers. Here too, the reaction is limited to difunctional siloxane species and the functional groups present are consumed during formation of the block copolymer so that no further functional groups for chemical crosslinking remain.

US 2016/0244610 describes compositions composed of mixtures of olefinically unsaturated MQ resins with polyphenylene ethers modified with unsaturation, wherein the use of the MQ resin is said to improve the dielectric and thermal properties of the polyphenylene ethers. However, the examples in US 2016/0244610 show very high dielectric loss factors of the compositions according to the invention.

Since the elucidation of the technical field in US 2016/0244610 makes special reference to the future development of communication technology, the invention must be regarded and evaluated in relation to the requirements of this field.

Having regard to the requirements and presently achieved performance of current materials with suitability for use for 5G applications, reference is made to US 2020/369855.

The unsatisfactory result for the inventive compositions according to US 2016/0244610 can be explained by the fact that the employed MQ resins are not compatible in the polyphenylene ether matrix. Since this factor too is clearly acknowledged and documented in the examples, the problem-solving character of the invention according to US 2016/0244610 is not apparent and said invention therefore fails to achieve its object without there being any discernable teaching or utility of the specified combinations for the field of wireless high-frequency communication technology. However, what US 2016/0244610 does demonstrate is the fact that homogeneous physical compositions of silicones, in this case silicone resins of the MQ type, with polyphenylene ethers are not always readily possible. The selection of especially suitable silicone resins which are compatible, readily processable and available in a suitable administration form and which allow synergistic enhancement of the positive properties both of the organic component of the polyphenylene ether and of the silicone component represents a particular challenge.

The incompatibility of the two employed components MQ resin and polyphenylene ether results in an inhomogeneous binder with phase interfaces due to the repulsion of the two incompatible polymers. Similarly to the known mode of action of anti-shrinkage additives, which function on account of their incompatibility in the surrounding matrix, inclusions of gas bubbles, generally air bubbles, can form between such incompatible phases. Air is undesirable in an electrical component for a number of reasons and is therefore always undesired. Air has different thermal expansion characteristics from the surrounding matrix and also from the copper foil with which the glass fiber composite is laminated. Air has a thermally insulating effect and prevents heat dissipation from a component. It provides a weak point for the penetration of moisture into the component, one of the greatest enemies of electronic applications. Moisture increases the dielectric loss factor. Evaporation of moisture after the laminating operation results in delamination of the copper foil and significantly reduces or completely annihilates the reliability of the component.

Similarly to US 2016/0244610, US 2018/0220530 also describes compositions composed of mixtures of silicone resins, in this case of the MT, MDT, MDQ and MTQ type, which are claimed generally and as classes without any particular limitation.

Similarly to US 2016/0244610 and US 2018/0220530, US 2018/0215971 also teaches compositions composed of mixtures of silicone resins, in this case of the TT and TQ type, which in this case too are claimed generally and in classes without any particular limitation, with vinyl- or methacrylate-functional polyphenylene ethers. According to the disclosures of the two inventions the compositions according to US 2018/0215971 and US 2018/0220530 show particular suitability for production of high-frequency circuit boards. It is noticeable that this prior art makes no reference whatsoever to the compatibility of the silicone resins resulting from the composition according to the invention and polyphenylene ethers with one another. Since the silicone resins are claimed as whole classes, part of the teaching of this prior art is that compositions of compatible and incompatible mixtures of silicone resins with polyphenylene ethers achieve the stated object equivalently. As set out above, this is implausible to a person skilled in the art.

It is apparent from comparative examples with vinyl-functional polydiorganosiloxanes that the polydiorganosiloxanes are less suitable for the application than the inventive MT, MDT, MDQ, MTQ, TT and TQ resins because the employed vinyl-functional polydiorganosiloxanes either result in a reduction in flexural strength or are volatile under the employed conditions of curing. A DT resin employed as a comparative example which, in contrast to the inventive TT and TQ resins, contains no olefinically unsaturated groups is likewise noninventive and therefore excluded from the claimed scope because the mechanical and thermal performance of this resin are described as inadequate for the target application. This apparently leads the inventors to the conclusion that even vinyl-functional DT resins cannot be inventive since they are completely excluded from the claimed scope.

US 2018/0215971 and US 2018/0220530 aim to achieve a dielectric loss factor<0.007. This requirement is achieved, albeit not by a significant margin, with freshly produced test specimens composed of the inventive materials. What US 2018/0215971 and US 2018/0220530 do not demonstrate is the long-term reliability of the inventive test specimens, i.e. the consistency of the dielectric properties under load. This would especially be relevant with regard to the compatibility/incompatibility of the components forming the binder which is not taken into account in US 2018/0215971 and US 2018/0220530. As has been demonstrated here this reliability under load is in fact not present and the prior art according to US 2018/0215971 and US 2018/0220530 therefore leaves plenty of room for improvement.

Going by the dielectric loss factors and the inadequate reliability of the inventive solutions according to US 2018/0215971 and US 2018/0220530 it is noticeable that the compositions according to US 2018/0215971 and US 2018/0220530 are much more costly than previously available solutions according to the prior art which achieve comparable dielectric loss factors much more economically. These inventions thus lack a teaching that makes a contribution to the prior art, and a realization of the inventions according to US 2016/0244610 US 2018/0215971 and US 2018/0220530 appears unlikely.

US 2020/0283575 teaches compositions of silane-terminated, olefinically unsaturated polyphenylene ethers obtained from the reaction of chlorofunctional silanes and hydroxy-terminated polyphenylene ethers in an anhydrous environment with unbranched linear or cyclic olefinically unsaturated or Si—H-functional polydiorganylsiloxanes. The compositions are cured by free-radical curing or by hydrosilylation.

In the silyl-terminated polyphenylene ethers according to the invention the silane units are bonded to the polyphenylene ether units exclusively through Si—O—C bonds. It is known that these bonds are sensitive to hydrolysis. In the presence of water and optionally heat and optionally catalytically active traces of acid an Si—O—C bond is reformed with reformation of the OH-terminated polyphenylene ether and an Si—O—Si coupling with optional intermediate formation of silanol species. Since the polyphenylene ethers are bonded to the olefinically unsaturated or Si—H-functional polydiorganosiloxanes only via the olefinically unsaturated silane units, hydrolysis of the Si—O—C bonds of the silane termination affords the physically blended components of the crosslinked polydiorganosiloxanes and the original polyphenylene ether. The result is essentially what would be expected if the polyphenylene ethers were to be mixed with the olefinically unsaturated polydiorganosiloxanes without preceding silane termination and the siloxane units were subsequently to be cured by free-radical curing.

The instability of the Si—O—C bond is often utilized for the synthesis of polyorganosiloxanes, such as for silicone resins on a large scale, see for example US 2017/0349709. In industrial processes the conditions for hydrolysis and condensation are specifically adjusted to obtain desired degrees of condensation and desired polyorganosiloxanes. In the present case with a binder according to US 2020/0283575 the reaction would proceed at an unforeseeable juncture and to an unforeseeable extent in the course of the service life of an electronic component. Since the noninventive examples of US 2020/0283575 teach that both pure polyorganosiloxane systems and pure polyphenylene ethers exhibit poorer performance than the inventive copolymers this means that the performance of the corresponding components decreases with time, wherein the speed with which this effect occurs depends on the environment in which the particular component is used. In a humid, for example maritime or tropical environment, the loss of performance would manifest more quickly than in a dry environment. This markedly restricts the applicability of the invention according to US 2020/0283575.

It is an object of the present invention to provide compatible compositions of polyorganosiloxanes with polyphenylene ethers that are suitable for use in high frequency applications and overcome the disadvantages of the prior art.

The invention provides a process for producing compositions, wherein

a) compounds selected from hydroxy-terminated homopolymeric or copolymeric polyphenylene ethers and phenols are reacted with

b) chlorosilane of formula (I) alone or in admixture with disiloxane of formula (IV)

R¹ₐR²_{b}SiCl_{4-a-b} (I),

[R¹_{(3-b)}R²_{b}Si]₂O (IV)

in the presence of water and solvent,

wherein

R¹ represents identical or different, optionally heteroatom-substituted aliphatic, cycloaliphatic or aromatic C1-C12 radicals, wherein the proportion of chlorosilanes of formula (I) having an aromatic radical is to be selected such that in the from the chlorosilane of formula (I) the proportion of aromatic substituents, based on 100 mol % of all radicals silicon-bonded by an Si—C bond, is at least 10 mol %,

R² represents a hydrogen atom, a mono- or polyunsaturated C2-C8 hydrocarbon radical which may additionally contain further acid-stable functional groups,

a=1, 2 or 3,

b=0, 1, 2 or 3,

with the proviso that a+b ≤3,

wherein in a mixture of different chlorosilanes of formula (I) at least one chlorosilane of formula (I) for which 4−a−b=3 must be present and the relative proportion of the chlorosilane of formula (I) for which 4−a−b=3 in the mixture with other chlorosilanes is at least 20 mol %,

wherein the disiloxanes of formula (IV) have a symmetrical structure, so that the radicals R¹ and R² on both silicon atoms each have the same definition, with the proviso that at most 60 mol % of disiloxanes of formula (IV) are employed based on the employed amount of chlorosilanes as 100 mol %.

The present invention also provides compositions producible from

a) compounds selected from hydroxy-terminated homopolymeric or copolymeric polyphenylene ethers and phenols with

b) chlorosilane of formula (I) alone or in admixture with disiloxane of formula (IV)

R¹ₐR²_{b}SiCl_{4-a-b} (I),

[R¹_{(3-b)}R²_{b}Si]₂O (IV)

in the presence of water and solvent,

wherein

R¹ represents identical or different optionally heteroatom-substituted aliphatic, cycloaliphatic or aromatic C1-C12 radicals, wherein the proportion of chlorosilanes of formula (I) having an aromatic radical is to be selected such that in the from the chlorosilane of formula (I) the proportion of aromatic substituents, based on 100 mol % of all radicals silicon-bonded by an Si—C bond, is at least 10 mol %,

R² represents a hydrogen atom, a mono- or polyunsaturated C2-C8 hydrocarbon radical which may additionally contain further acid-stable functional groups,

a=1, 2 or 3,

b=0, 1, 2 or 3,

with the proviso that a+b ≤3,

wherein in a mixture of different chlorosilanes of formula (I) at least one chlorosilane of formula (I) for which 4−a−b=3 must be present and the relative proportion of the chlorosilane of formula (I) for which 4−a−b=3 in the mixture with other chlorosilanes is at least 20 mol %,

wherein the disiloxanes of formula (IV) have a symmetrical structure, so that the radicals R¹ and R² on both silicon atoms each have the same definition, with the proviso that at most 60 mol % of disiloxanes of formula (IV) are employed based on the employed amount of chlorosilanes as 100 mol %.

It has surprisingly been found that the compositions achieve the object. The compositions are homogeneous and stable since under controlled conditions the hydrolysis assumes a steady state which results in a physical mixture from the outset and the performance-stabilized product mixture is thus employed as a binder. The performance requirements for use in high-frequency applications are met. This is not the case for the compositions according to US 2020/0283575.

The compositions contain polyphenylene ethers, polyorganosiloxanes comprising polyphenylene ether radicals and optionally polyorganosiloxanes comprising no polyphenylene ether radicals.

The present invention likewise provides the polyorganosiloxanes comprising polyphenylene ether radicals producible by the process.

The process preferably comprises a subsequent workup by prior art methods comprising the steps of phase separation, washing to neutrality, optionally blending with further polyphenylene ethers and devolatilization, wherein the sequence of the steps may be adapted as required.

It is preferable when the proportion of chlorosilanes of formula (I) having an aromatic radical is to be selected such that in the polyorganosiloxane formed from the chlorosilane of formula (I) or a mixture of different chlorosilanes of formula (I) the proportion of aromatic substituents, based on 100 mol % of all radicals silicon-bonded by an Si—C bond and introduced via the chlorosilane(s) of formula (I), is at least 15 mol %, in particular at least 20 mol %.

The relative proportion of the chlorosilane of formula (I) for which 4−a−b=3 in admixture with other chlorosilanes is preferably at least 30 mol %, in particular at least 40 mol %. It is especially also permissible to employ exclusively chlorosilanes of formula (I) for which 4−a−b=3.

Reaction by the process according to the invention described below converts these chlorosilanes of formula (I) for which 4−a−b=3 into resin building blocks of formula (R¹SiO_{3/2}), (R¹R³SiO_{2/2}) and (R¹R³²SiO_{1/2}) wherein R¹ is as defined above and R³ has the same definition as R² and can additionally represent a radical formed during formation of the silicone resin by the process according to the invention, i.e. a hydroxyl group or a polyphenylene ether radical bonded to the silicon atom via oxygen or an optionally substituted phenol radical bonded to the silicon atom via oxygen. R³ is not an alkoxy group. This is ruled out as not in accordance with the invention.

Further preferred chlorosilanes of formula (I) are those for which 4−a−b=1, i.e. which in the produced polyorganosilane structure result in so-called M units which in the present inventive case conform to the formulae (R¹²R²SiO_{1/2}), (R¹R²²SiO_{1/2}), (R¹³SiO_{1/2}) or (R²³SiO_{1/2}), wherein R¹ and R² are as defined above.

Particularly preferred chlorosilanes of formula (I) for which 4−a−b=1 are those which result in M units of formulae (R¹²R²SiO_{1/2}) and (R¹³SiO_{1/2}), in particular those which result in M units of formula (R¹²R²SiO_{1/2}).

The relative proportion of these chlorosilanes of formula (I) for which 4−a−b=1 in admixture with other chlorosilanes is at most 50 mol %, preferably at most 40 mol %, in particular most 30 mol %.

The process for producing the compositions according to the invention is described in detail below. Substances which can introduce alkoxy groups into the polyorganosiloxane structure, such as alcohols or alkyl esters of carboxylic acids, for instance those of acetic acid, and also for example propyl, ethyl or methyl acetate, have consciously been avoided. Silicon-bonded alkoxy groups, especially having short carbon radicals, are under suitable conditions capable of thermal or hydrolytic condensation to form Si—O—Si bonds and eliminate low molecular weight volatile alcohols, which can lead to bubble formation or other defects in the binder matrix and on account of their polarity have and adverse effect on the dielectric properties, thus adversely affecting the performance and reliability of an electrical component for high-frequency technology.

The polyorganosiloxanes according to the invention may also contain structural elements of formulae (R¹₂SiO_{2/2}), (R³₂SiO_{2/2}) or (R¹R³SiO_{2/2}) und (SiO_{4/2}) which are obtainable from the corresponding chlorosilanes of formula (I), wherein R¹ and R³ are as defined above.

If the inventive phenyl-containing polyorganosiloxanes comprising polyphenylene ether radicals that are obtained in the form of the partially hydrolyzed copolymers of phenyl-containing polyorganosiloxanes with polyphenylene ethers or unsubstituted phenol or substituted phenols are isolated they preferably have average molecular weights Mw in the range from 500 to 300 000 g/mol, preferably from 600 to 100 000 g/mol, particularly preferably from 600 to 60 000 g/mol, in particular from 600 to 40 000 g/mol, wherein the polydispersity is at most 20, preferably at most 18, particularly preferably at most 16, in particular at most 15. The phenyl-containing polyorganosiloxanes are solid at 25° C., wherein the solid phenyl-containing polyorganosiloxanes have glass transition temperatures in the uncrosslinked state in the range from 25° C. to 250° C., preferably from 30° C. to 230° C., in particular from 30° C. to 200° C., or are liquid with viscosities at 25° C. of 20 to 8 000 000 mPas, preferably of 20 to 5 000 000 mPas, in particular of 20 to 3 000 000 mPas. Very particularly suitable are phenyl-containing polyorganosiloxanes that are solid at 25° C. and have a glass transition temperature of 45-200° C. or that are liquid with a viscosity between 300 and 1 000 000 mPas.

Selected examples of preferred radicals R¹ are alkyl radicals, such as the methyl, ethyl, n-propyl, isopropyl, n-butyl, isobutyl, tert-butyl, n-pentyl, isopentyl, neopentyl and tert-pentyl radical, hexyl radicals, such as the n-hexyl radical, heptyl radicals, such as the n-heptyl radical, octyl radicals, such as the n-octyl radical, and isooctyl radicals, such as the 2,2,4-trimethylpentyl radical, nonyl radicals, such as the n-nonyl radical, decyl radicals, such as the n-decyl radical, dodecyl radicals, such as the n-dodecyl radical, and octadecyl radicals, such as the n-octadecyl radical, cycloalkyl radicals, such as cyclopentyl, cyclohexyl, cycloheptyl and methylcyclohexyl radicals, aryl radicals, such as the phenyl, naphthyl, anthryl and phenanthryl radical, alkaryl radicals, such as tolyl radicals, xylyl radicals and ethylphenyl radicals, and aralkyl radicals, such as the benzyl radical and the α- and β-phenylethyl radicals and glycol radicals such as polypropylene glycol articles and polyethylene glycol radicals, wherein this list is not to be understood as limiting.

Radical R¹ is preferably selected from unsubstituted hydrocarbon radicals having 1 to 12 carbon atoms, particularly preferably the methyl, ethyl and n-propyl radical and phenyl radical, in particular the methyl, n-propyl and phenyl radical. The methyl radical and the phenyl radical are particularly preferred.

As mentioned above a minimum proportion of aromatic radicals R¹ must be present in the polyorganosiloxane formed from the chlorosilane(s) of formula (I). This minimum proportion is necessary to produce good homogeneous compatibility with polyphenylene ethers. Purely alkyl-substituted polyorganosiloxanes are not homogeneously miscible with polyphenylene ethers. Inhomogenous mixtures result in the cured binder in domain formation with larger or smaller domains and consequently in inhomogeneous position-dependent performance of the component determined by the particular excess of the one or the other component. This is undesirable and is efficaciously avoided through homogeneous adjustment of miscibility through a suitable molecular composition of the polyorganosiloxane. This also improves the heat-resistance of the mixture.

In inhomogeneous mixtures of incompatible polyorganosiloxanes with polyphenylene ethers interfaces form between the silicone domains and the surrounding organic polymer on account of the incompatibility. Air inclusions and, as a consequence, incorporation of moisture cannot be ruled out at such interfaces.

Selected examples of radicals R² are acrylate and methacrylate radicals such as methyl acrylate, methyl methacrylate, ethyl acrylate, ethyl methacrylate, propyl acrylate, propyl methacrylate, n-butyl acrylate, n-butyl methacrylate, isobutyl acrylate, isobutyl methacrylate, t-butyl acrylate, t-butyl methacrylate, 2-ethylhexyl acrylate and norbornyl acrylate, wherein methyl acrylate, methyl methacrylate, n-butyl acrylate, isobutyl acrylate, t-butyl acrylate, 2-ethylhexyl acrylate and norbornyl acrylate are particularly preferred.

Further examples of radicals R² are olefinically or acetylenically unsaturated hydrocarbon radicals of formulae (II) and (III)

Y—CR⁴═CR⁵R⁶ (II)

Y—C≡CR⁷ (III),

wherein Y is a chemical bond or a divalent linear or branched hydrocarbon radical having up to 30 carbon atoms, wherein Y can also contain olefinically unsaturated groups or heteroatoms and the atom bonded directly from the radical Y to the silicon is a carbon. Heteroatom-containing fragments that may typically be present in the radical Y¹ are —C—O—C—, —C(═O)—, —O—C(═O)—, —O—C(═O)—O—, wherein asymmetrical radicals may be incorporated into the radical Y in both possible directions, wherein R⁴, R⁵, R⁶ and R⁷ represent a hydrogen atom or a C1-C8 hydrocarbon radical which may optionally contain heteroatoms, wherein heteroatom-free hydrocarbon radicals are preferred and wherein the hydrogen atom is the most preferred radical for R⁴, R⁵, R⁶ and R⁷. Particularly preferred radicals (II) are the vinyl radical, the propenyl radical and the butenyl radical, in particular the vinyl radical. The radical (II) may also be a dienyl radical bonded via a spacer, such as the spacer-bonded 1,3-butadienyl radical or the isoprenyl radical.

Further examples of radicals R² are the hydridic silicon-bonded hydrogen.

Apart from the hydrogen that is always silicon-bonded, the radicals R² are generally not directly bonded to the silicon atom. An exception to this are the olefinic or acetylenic groups, which may also be directly silicon-bonded, especially the vinyl group. The remaining functional groups R² are bonded to the silicon atom via spacer groups, wherein the spacer is always Si—C bonded. The spacer is a divalent hydrocarbon radical which comprises 1 to 30 carbon atoms and in which nonadjacent carbon atoms may be replaced by oxygen atoms and which can also contain other heteroatoms or heteroatom groups, though this is not preferred.

The methacrylate group and the acrylate group are preferably bonded via a spacer, wherein the spacer is composed of 3 to 15 carbon atoms, preferably in particular 3 to 8 carbon atoms, in particular 3 carbon atoms and optionally also a divalent hydrocarbon radical comprising at most 3 oxygen atoms, preferably at most 1 oxygen atom, bonded to the silicon atom.

Examples of suitable solvents are aromatic solvents such as toluene, xylene, ethylbenzene or mixtures thereof and hydrocarbons or mixtures thereof such as commercially available isoparaffin mixtures for example.

Alcohols, as well as liquid polyols and organic carboxylic esters such as for example those of acetic acid, for instance ethyl acetate, butyl acetate, methoxypropyl acetate, are not suitable since they result in introduction of additional alkoxy groups into the polyorganosiloxane structure which is to be avoided since said groups can lead to bubbles in the cured binder matrix through condensation with elimination of volatile alcohols upon exposure to heat. The content of condensable groups should therefore be kept to a minimum. The process described in detail below therefore takes particular account of this requirement of freedom from alkoxy groups. Alkoxy-free products are thus obtained.

If the chlorosilanes of formula (I) are employed in admixture with one or more disiloxanes of formula (IV) they are employed, based on the employed amount of chlorosilane as 100 mol %, in an amount of at most 50 mol %, particularly preferably at most 40 mol %, in particular at most 30 mol %.

### Polyphenylene Ethers:

The polyphenylene ethers employed according to the invention which are reacted according to the process described in detail below are hydroxy-terminated functional homopolymers or copolymers which are preferably producible by repeated oxidative coupling of at least one type of phenol components of formula (V) in the presence of oxygen or an oxygen-containing gas and an oxidative coupling catalyst.

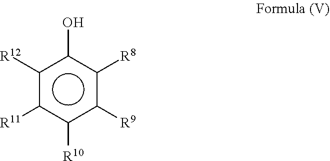

In formula (V) R⁸, R⁹, R¹⁰, R¹¹ and R¹² independently of one another represent a hydrogen radical, a hydrocarbon group or a heteroatom-substituted hydrocarbon group with the proviso that at least one of the radicals R⁸, R⁹, R¹⁰, R¹¹ and R¹² always represents a hydrogen radical, wherein the radical R¹⁰ preferably represents a hydrogen radical.

Examples of radicals R⁸, R⁹, R¹⁰, R¹¹ and R¹² in formula (V) are the hydrogen radical, saturated hydrocarbon radicals such as the methyl, ethyl, n-propyl, isopropyl radical, the primary, secondary and tertiary butyl radical, the hydroxyethyl radical, aromatic radicals such as the phenylethyl radical, the phenyl radical, the benzyl radical, the methylphenyl radical, the dimethylphenyl radical, the ethylphenyl radical, heteroatom-containing radicals such as the hydroxymethyl radical, the carboxyethyl radical, the methoxycarbonylethyl radical and the cyanoethyl radical and acrylate and methacrylate radicals, such as methyl acrylate, methyl methacrylate, ethyl acrylate, ethyl methacrylate, propyl acrylate, propyl methacrylate, n-butyl acrylate, n-butyl methacrylate, isobutyl acrylate, isobutyl methacrylate, t-butyl acrylate, t-butyl methacrylate, 2-ethylhexyl acrylate and norbornyl acrylate, olefinically or acetylenically unsaturated hydrocarbon radicals of formulae (II) and (III).

The adjacent radicals R⁸ and R⁹ and the adjacent radicals R¹¹ and R¹² may optionally also be connected to one another to form the same cyclic saturated or unsaturated radical, thus forming annelated polycyclic structures.

Examples of phenolic compounds of formula (V) are phenol, ortho-, meta- or para-cresol, 2,6-, 2,5-, 2,4- or 3,5-dimethylphenol, 2-methyl-6-phenylphenol, 2,6-diphenylphenol, 2,6-diethylphenol, 2-methyl-6-ethylphenol, 2,3,5-, 2,3,6- or 2,4,6-trimethylphenol, 3-methyl-6-t-butyl phenol, thymol and 2-methyl-6-allyl phenol. Preferred phenolic compounds of formula (V) are 2,6-dimethylphenol, 2,6-diphenylphenol, 3-methyl-6-t-butylphenol and 2,3,6-trimethylphenol.

The phenolic compounds of formula (V) may be copolymerized with polyhydric aromatic compounds such as for example bisphenol A, resorcinol, hydroquinone and novolac resins.

In the context of the present invention these copolymers are also included under the term polyphenylene ethers.

The oxidative coupling catalyst used for the oxidative copolymerization of said phenyl compounds is not particularly limited. It is in principle possible to employ any catalyst capable of catalyzing oxidative couplings.

The process of oxidative copolymerization of phenolic compounds to produce polyphenylene ethers is described for example in U.S. Pat. No. 3,306,874.

Examples of typical polyphenylene ethers of the present invention are

poly(2,6-dimethyl-1,4-phenylene ether),

poly(2,6-diethyl-1,4-phenylene ether),

poly(2-methyl-6-ethyl-1,4-phenylene ether),

poly(2-methyl-6-propyl-1,4-phenylene ether),

poly(2,6-dipropyl-1,4-phenylene ether),

poly(2-ethyl-6-propyl-1,4-phenylene ether),

poly(2,6-dibutyl-1,4-phenylene ether),

poly(2,6-dipropenyl-1,4-phenylene ether),

poly(2,6-dilauryl-1,4-phenylene ether),

poly(2,6-diphenyl-1,4-phenylene ether),

poly(2,6-dimethoxy-1,4-phenylene ether),

poly(2,6-diethoxy-1,4-phenylene ether),

poly(2-methoxy-6-ethoxy-1,4-phenylene ether),

poly(2-ethyl-6-stearyloxy-1,4-phenylene ether),

poly(2-methyl-6-phenyl-1,4-phenylene ether),

poly(2-methyl-1,4-phenylene ether),

poly(2-ethoxy-1,4-phenylene ether),

poly(3-methyl-6-tert-butyl-1,4-phenylene ether),

poly(2,6-dibenzyl-1,4-phenylene ether) and copolymers of repeating units of the components listed above as examples.

Further examples which in the context of the present invention are included in the term polyphenylene ethers are those formed from higher-substituted phenols, such as for example 2,3,6-trimethylphenol and 2,3,5,6-tetramethylphenol with a phenyl substituted in the 2-position such as 2,6-dimethylphenol.

Preferred polyphenylene ethers from the list above are poly(2,6-dimethyl-1,4-phenylene ether) and copolymers of 2,6-dimethylphenol with 2,3,6-trimethylphenol and of 2,6-dimethylphenol with bisphenol A.

The polyphenylene ethers employed according to the invention may be graft copolymers obtained by grafting the abovementioned polymers and copolymers with styrene components, such as for example styrene, alpha-methylstyrene, para-methylstyrene and vinylstyrene. Such graft copolymers are likewise within the scope of the present invention.

The polyphenylene ethers may optionally be employed in combination with other components, for example thermoplastic polymers such as for instance polystyrene, styrene-based elastomers and polyolefins, which are optionally employed for specifically improving individual properties, such as for instance processability and impact strength and optionally other properties. These components are referred to herein as component (C).

Polystyrene is to be understood as meaning that at least 25% by weight of the repeating units are of vinylaromatic origin and are represented by the following formula (VI).

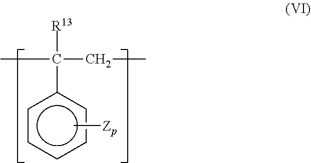

In formula (VI) R¹³ represents a hydrogen radical or a hydrocarbon group having 1-4 carbon atoms, such as for example a methyl group, an ethyl group, a propyl group or a butyl group.

Z is an alkyl group having 1-4 carbon atoms such as for example a methyl group, an ethyl group, a propyl group or a butyl group. p is an integer, wherein p may assume the values of 0 to 5 inclusive.

Examples of polystyrene components of formula (VI) are homopolymers and copolymers of styrene and its derivatives such as alpha- and para-methylstyrene and an elastomer-modified high-impact polystyrene (high impact polystyrene=HIPS) comprising 70-99% by weight of repeating units of formula (VI) and 1-30% by weight of a diene rubber.

Examples of diene rubber-forming HIPS are homopolymers and copolymers of conjugated dienes such as butadiene, isoprene and chloroprene, copolymers of said conjugated dienes with unsaturated nitrile components such as acrylonitrile and methacrylonitrile and/or aromatic vinyl compounds such as styrene, alpha- and para-methylstyrene, chloro- and bromostyrene and mixtures thereof.

Preferred diene rubbers are polybutadienes and butadiene-styrene copolymers. The production processes for the HIPS are known prior art and comprise the processes of emulsion polymerization, suspension polymerization, bulk polymerization, solution polymerization and combinations thereof.

The content of polystyrenes, provided they are present in the polyphenylene ether, is preferably between 1 and 1000 parts by mass, particularly preferably between 10 and 500 parts by mass, based on 100 parts by mass of polyphenylene ether.

Styrene-based elastomers are well-known prior art. The selection thereof is not limited in any particular way. Examples include styrene-butadiene block copolymers having at least one polystyrene block and at least one polybutadiene block, styrene-isoprene copolymers having at least one polystyrene block and at least one polyisoprene block, block copolymers having at least one polystyrene block and at least one isoprene-butadiene copolymer block, block copolymers in which unsaturated bond proportions of the polyisprene block, of the polybutadiene block and of the isoprene-butadiene copolymer block in the abovementioned block copolymers are selectively hydrogenated and which continue to be referred to as hydrogenated block copolymers and graft copolymers obtained by graft polymerization of a polyolefin elastomer with styrene, wherein the polyolefin elastomer is produced by copolymerization of two or more monomers selected from the group of ethylene, propylene, butene and the abovementioned conjugated dienes, wherein the graft copolymer continues to be referred to as a styrene-grafted polyolefin.

Among these, the hydrogenated block copolymers and the styrene-grafted polyolefins are preferred.

The polyolefins are not limited in any particular way and comprise the representatives known from the prior art.

Examples of polyolefins are polyethylene, polypropylene, polybutene, polypentene, ethylene-vinyl acetate copolymers, ethylene-vinyl alcohol copolymers, ethylene-propylene rubbers and ethylene-propylene-diene rubbers.

The polyphenylene ethers employed according to the invention are preferably not graft copolymers.

Preferred polyphenylene ethers employed according to the invention, which are reacted with chlorosilanes of formula (I) and optionally disiloxanes of formula (IV) in the process according to the invention, have the formula (VII),

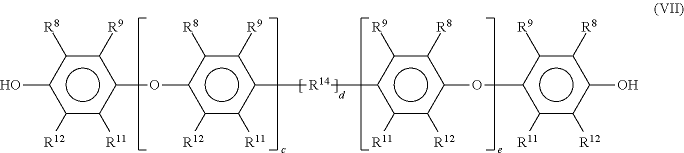

wherein these may be grafted with polystyrene copolymers as described but preferably are not.

The radicals R⁸, R⁹, R¹¹ and R¹² are independently of one another as defined above. The radical R¹⁴ represents a chemical bond or a divalent, optionally substituted arylene radical of the form (—C6R¹⁵₄—), wherein R¹⁵ independently thereof may have the same definition as the radicals R⁸, R⁹, R¹¹ or R¹², or an alkylene radicals of the form —CR¹⁶₂—, wherein R¹⁶ independently of R¹⁵ may have the same definitions as R¹⁵, a divalent glycol radical of the form —[(OCH₂)₂O]_{f}— or —[(OCH₂CH(CH₃)₂)O]_{g}—, wherein f and g may each independently of one another represent integers in the value of in each case 1 to 50 inclusive, a divalent silyloxy radical of the form —Si(R¹⁷)_{202/2}—, a divalent siloxane radical of the form —[(CH₂)₃Si—[O—Si(R¹⁸)₂]ₕO—Si(CH₂)₃—, a divalent silyl radical of the form —Si(R¹⁹)₂—, wherein R¹⁷, R¹⁸ and R¹⁹ independently of one another and independently of R¹⁵ may have the same definitions as R¹⁵, and h is an integer having a value of in each case 0 to 500 inclusive.

Preferred radicals R¹⁴ are the chemical bond, the —CH₂— radical, the C(CH₃)₂— radical, the —C(C₆H₅)₂— radical and the —[(CH₂)₃Si—[O—Si(R¹⁸)_{2]}O—Si(CH₂)₃— radical.

c, d and e are integers, wherein

c is an integer having a value of in each case 2 to 50 inclusive,

d is an integer having a value of in each case 1 to 10 inclusive and

e is an integer having a value of in each case 2 to 50 inclusive.

The phenols which are reacted with chlorosilanes of formula (I) and optionally disiloxanes of formula (IV) in the process according to the invention have the formula (V).

The polyorganosiloxanes according to the invention which comprise polyphenylene ether radicals, in particular partially hydrolyzed polyorganosiloxane-polyphenylene ether copolymers or partially hydrolyzed polyorganosiloxane-phenol copolymers, obtained by reacting the chlorosilanes of formula (I) and optionally the disiloxanes of formula (IV) with polyphenylene ethers of formula (VII) or phenols of formula (V) have the formula (VIII),

(R¹₃₋ᵢR³ᵢSiO_{1/2})ⱼ(R¹₂₋ₖR³ₖSiO_{2/2})ₗ(R¹SiO_{3/2})ₘ(R³SiO_{3/2})ₙ(SiO_{4/2})ₒ (VII)

wherein

R¹ and R³ are as defined above,

i may be an integer having values of 0, 1, 2 or 3, but preferably has values of 0 or 1, in particular the value 1,

k may be an integer having values of 0, 1 or 2, but preferably has values of 0 or 1, in particular the value 0,

j, l, m, n and o are integers, wherein

j may assume the values 0 to 50,

l may assume the values 0 to 1900,

m may assume the values 0 to 2500,

n may assume the values 0 to 2000, wherein m+n≥2

o may assume the values 0 to 75,

wherein the value m+n makes up at least 20%, preferably at least 30%, in particular at least 40%, of the total value j+l+m+n+0, the value of l has a proportion of at most 50%, in particular at most 30%, the value of j makes up a proportion of at most 80% of the total, wherein the value of j preferably makes up a proportion of 10% to 50% of the total and the value of o has a proportion of at most 50%, in particular most 30%, of the total, wherein the total j+l+m+n+0 ≥6.

The arrangement of the building blocks (R¹₂₋ₖR³ₖSiO_{2/2})ₗ, (R¹SiO_{3/2})ₘ, (R³SiO_{3/2})ₙ and (SiO_{4/2}). may be random or blockwise. This means that building blocks (R¹₂₋ₖR³ₖSiO_{2/2})ₗ, (R¹SiO_{3/2})ₘ, (R³SiO_{3/2})ₙ and (SiO_{4/2}). units alternate randomly in the molecular structure or blocks of two or more repeating units of identical form, i.e. of(R¹₂₋ₖR³ₖSiO_{2/2})ₗ or (R¹SiO_{3/2})ₘ or (R³SiO_{3/2})ₙ or (SiO _{4/2})ₒ or (R¹₂₋ₖR³ₖSiO_{2/2})ₗ, are present next to blocks of two or more repeating units of the respective other building blocks, wherein at least 3 identical building blocks must be combined with one another to form a block in order to obtain an effective block structure. Effective is to be understood as meaning that comparison of the block copolymeric structures with the random structures reveal differences in mechanical characteristics. In the case of the block copolymeric structures of formula (VIII) j+l+m+n+0≥9.

In the polyorganosiloxanes of formula (VIII) a sufficient amount of Si—C-bonded aromatic radicals R¹ must always be present. It is irrelevant whether the radicals R¹ are bonded to an M, D or T unit. An M unit is a siloxane unit which has three Si—C-bonded radicals and is bonded to an adjacent silicon atom and thus incorporated into the remaining polyorganosiloxane structure via an oxygen atom. A D unit is a siloxane unit which has two Si—C-bonded radicals and is bonded to adjacent silicon atoms and thus incorporated into the remaining polyorganosiloxane structure via two oxygen atoms. A T unit is a siloxane unit which has one Si—C-bonded radicals and is bonded to adjacent silicon atoms and thus incorporated into the remaining polyorganosiloxane structure via three oxygen atoms.

It is preferable when at least 15 mol % of aromatic Si—C-bonded radicals R¹ based on all Si—C-bonded aromatic and aliphatic radicals calculated as 100 mol % are present, particularly preferably at least 20 mol %, in particular at least 25 mol %. The preferred aromatic radical R¹ is the phenyl radical.

The polyorganosiloxanes of formula (VIII) according to the invention moreover have at least 0.3 mol % of Si—O—C-bonded, optionally substituted phenol radicals as obtained from formula (V) by abstraction of the phenolic hydrogen atom and addition reaction of the resulting phenol radical onto a silicon-bonded oxygen or polyphenylene ether radicals as obtained from formula (VII) by abstraction of at least one terminal phenolic hydrogen atom and addition reaction of the resulting polyphenylene ether radical onto a silicon-bonded oxygen as radicals R³. It is preferable when at least 0.4 mol %, in particular at least 0.5 mol %, of such radicals R³ are present. These radicals R³ which have survived the hydrolytic conditions of the process undamaged, are surprisingly in stably-bonded form despite the Si—O—C bond and result in the inventive, permanent and sustainable compatibilization of the inventive partially hydrolyzed polyorganosiloxane-phenol/polyorganosiloxane-polyphenylene ether copolymers.

The process according to the invention is particularly efficient when the molar ratio of all Si—C-bonded aromatic and aliphatic radicals R¹ expressed as a fraction

$$\frac{Molzahl aromatische Reste {R}^{1}}{Molzahl aromatische Reste {R}^{1} + Molzahl aliphatische Reste {R}^{1}}$$

assumes values of 1.0 to 0.05. If fewer aromatic groups present, i.e. the value of the mole fraction is <0.05, even the inventive modification of the polyorganosiloxanes by partial hydrolysis of the copolymers of the optionally substituted phenols or polyphenylene ethers with the polyorganosiloxane will not achieve particularly good compatibilization with polyphenylene ethers.

The values of the abovementioned mole fraction are preferably between 0.1 and 0.95, particularly preferably between 0.2 and 0.95, in particular between 0.4 and 0.8.

The most preferred aliphatic radical R¹ is the methyl radical. The most preferred combination of aromatic and aliphatic radicals is the combination of phenyl radicals with methyl radicals.

In addition to the polyphenylene ethers reacted with the chlorosilanes of formula (I) and the disiloxanes of formula (IV) employed according to the invention the obtained reaction products may be admixed with further polyphenylene ethers that may be but need not be distinguishable from the polyphenylene ethers used for reaction with the chlorosilanes of formula (I) and the disiloxanes of formula (IV). In particular, these additionally admixed polyphenylene ethers may contain further radicals on the phenolic oxygen atom, as described for the radicals R⁸, R⁹, R¹⁰, R¹¹ and R¹², i.e. also radicals distinct from hydrogen.

It is in principle also conceivable to use polyphenylene ethers substituted at the phenolic oxygen in the reaction with chlorosilanes of formula (I) and the disiloxanes of formula (IV) but this is not preferred in order to rule out possibly disruptive side reactions of the functional groups bonded to the phenolic oxygen. It is preferable to use only polyphenylene ethers reactive to chlorosilanes that have an unsubstituted phenolic OH group. It is in any case necessary for the process according to the invention to employ at least one species of polyphenylene ethers or phenols that is reactive to chlorosilanes via an unsubstituted phenolic OH group.

It is possible to incorporate fillers into the compositions according to the invention, wherein the selection thereof is not limited in any particular way. Examples of reinforcing fibers are glass fibers, carbon fibers or aramid fibers, wherein glass fibers are preferred.

Inorganic fillers are silica, alumina, calcium carbonate, talc, mica, clay, kaolin, magnesium sulfate, carbon black, titanium dioxide, zinc oxide, antimony trioxide and boron nitride. Further examples of further components are antioxidants, stabilizers against weathering, lubricants, flame retardants, plasticizers, colorants, antistats and demolding agents.

The compositions of the invention are chemically curable, i.e. are chemically curable to afford a crosslinked insoluble network via a chemical reaction. Curing is carried out via the organofunctional groups R² described above. This typically employs either a free-radical polymerization reaction for curing or, if in addition to the olefinically or ethylenically unsaturated functional groups R², silicon-bonded hydrogen is also present as a radical, a hydrosilylation curing.

If the compositions are to be cured a sufficient amount of functional groups is preferably present. To achieve sufficient curing an average of at least 1.2 functional groups must be present per molecule of the polyorganosiloxanes comprising polyphenylene ether radicals, preferably an average of at least 1.5 and in particular an average of at least 1.8 functional groups per molecule of the polyorganosiloxanes comprising polyphenylene ether radicals.

As examples of suitable initiators to initiate the free-radical polymerization reference is here especially made to examples from the field of organic peroxides, such as di-tert-butyl peroxide, dilauryl peroxide, dibenzoyl peroxide, dicumyl peroxide, cumyl peroxyneodecanoate, tert-butyl peroxyneodecanoate, tert-amyl peroxypivalate, tert-butyl peroxypivalate, tert-butyl peroxyisobutyrate, tert-butyl peroxy-3,5,5-trimethylhexanoate, tert-butylcumyl peroxide, tert-butyl peroxyacetate, tert-butyl peroxybenzoate, 1,1-di-tert-butylperoxycyclohexane, 2,2-di(tert-butylperoxy)butane, bis(4-tert-butylcyclohexyl) peroxydicarbonate, hexadecyl peroxydicarbonate, tetradecyl peroxydicarbonate, dibenzyl peroxydicarbonate, diisopropylbenzene dihydroperoxide, [1,3-phenylenebis(1-methylethylidene)]bis[tert-butyl]peroxide, 2,5-dimethyl-2,5-di-(tert-butylperoxy)hexane, dicetyl peroxydicarbonate, acetylacetone peroxide, acetylcyclohexanesulfonyl peroxide, tert-amyl hydroperoxide, tert-amyl peroxy-2-ethylhexanoate, tert-amyl peroxy-2-ethylhexylcarbonate, tert-amyl peroxyisopropylcarbonate, tert-amyl peroxyneodecanate, tert-amyl peroxy-3,5,5-trimethylhexanoate, tert-butyl monoperoxymaleate, wherein this list is only illustrative and not limiting. It is optionally also possible to employ mixtures of different initiators for free-radical reactions. The suitability of an initiator or initiator mixture for free-radical reactions depends on its decomposition kinetics and the requirement conditions to be met. Sufficiently taking into account these boundary conditions will allow a person skilled in the art to choose a suitable initiator.

In the case of compositions containing not only olefinically and acetylenically unsaturated groups but also silicon-bonded hydrogen, curing may also be effected by means of a hydrosilylation reaction. Suitable catalysts for promoting the hydrosilylation reaction are the known catalysts from the prior art.

Examples of such catalysts are compounds or complexes from the group of noble metals containing platinum, ruthenium, iridium, rhodium and palladium, preferably metal catalysts from the group of platinum group metals or compounds and complexes from the group of platinum group metals. Examples of such catalysts are metallic and finely divided platinum which may be supported on supports such as silicon dioxide, aluminum oxide or activated carbon, compounds or complexes of platinum such as platinum halides, for example PtCl₄, H₂PtCl_{X}6H₂O, Na₂PtCl_{4X}4H₂O, platinum-olefin complexes, platinum-alcohol complexes, platinum-alkoxide complexes, platinum-ether complexes, platinum-aldehyde complexes, platinum-ketone complexes, including reaction products of H₂PtCl_{4X}6H₂O and cyclohexanone, platinum-vinylsiloxane complexes such as platinum-1,3-divinyl-1,1,3,3-tetramethyldisiloxane, with or without a content of detectable inorganically bound halogen, bis(gamma-picoline)platinum chloride, trimethylenedipyridineplatinum chloride, Dicyclopentadieneplatinum dichloride, dimethylsulfoxyethenylplatinum(II) dichloride, cyclooctadieneplatinum dichloride, norbornadieneplatinum dichloride, gammapicolineplatinum dichloride, cyclopentadieneplatinum dichloride and reaction products of platinum tetrachloride with olefin and primary or secondary amine or primary and secondary amine such as the reaction product of platinum tetrachloride dissolved in 1-octene with sec-butylamine or ammonium platinum complexes. In a further embodiment of the process according to the invention complexes of iridium with cyclooctadienes, such as for example u-dichlorobis(cyclooctadiene)diiridium(l), are used.

This list is only illustrative and not limiting. The development of hydrosilylation catalysts is a dynamic field of research that constantly yields new active species that may naturally also be employed here.

The hydrosilylation catalyst is preferably selected from compounds or complexes of platinum, preferably preferably platinum chlorides and platinum complexes, in particular platinum-olefin complexes and particularly preferably platinum-divinyltetramethyldisiloxane complexes.

In the process according to the invention the hydrosilylation catalyst is employed in amounts of 2 to 250 ppm by weight, preferably in amounts of 3 to 150 ppm, in particular in amounts of 3 to 50 ppm, based on the total compositions

In addition to the polyphenylene ethers used for reaction with the chlorosilanes of formula (I)the obtained compositions according to the invention may be admixed with further polyphenylene ethers in order optionally to establish a higher proportion of organic components in the mixture.

Both the polyphenylene ethers used for reaction with the chlorosilanes of formula (I) and polyphenylene ethers distinct therefrom are suitable therefor.

Polyphenylene ethers substituted at the phenolic oxygen which may be employed as a further blend component include for example those of formula (IX)

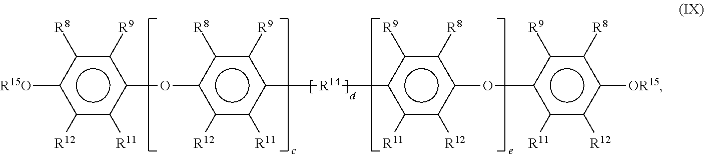

wherein the radicals R⁸, R⁹, R¹¹, R¹² and R¹⁴ are as defined above and R¹⁵ represents a mono- or polyunsaturated aliphatic or cycloaliphatic C2-C18 hydrocarbon radical which may additionally contain heteroatoms and further functional groups and may be substituted by further aromatic hydrocarbon groups, wherein R¹⁵ may also be bonded to the phenolic hydrogen by an atom other than a carbon atom. The radical R¹⁵ may thus also contain silyl groups for example, where the silicon atom is directly bonded to the phenolic oxygen and the unsaturated hydrocarbon radical is bonded to the silicon atom. As examples of such silyl-substituted polyphenylene ethers reference is made to the polyphenylene ethers of formula (I) in US 2020/0283575. Otherwise, examples of unsaturated hydrocarbon radicals R¹⁵ are the same as those recited above for R².

### Process:

Producing the compositions according to the invention is carried out in a process which preferably comprises the process steps of:

1) production of a reactant initial charge by mixing the chlorosilane(s) of formula (I), optionally together with the disiloxane(s) of formula (IV) and the polyphenylene ethers preferably of formula (VII) and/or phenols of formula (V) in an aromatic solvent,

2) production of an initial charge of pH-neutral, preferably demineralized, water,

3) addition of the reactant initial charge from step 1) to the water initial charge from step 2),

4) hydrolysis and condensation and

5) purification of the obtained mixture of polyphenylene ether, polyorganosiloxanes comprising polyphenylene ether radicals and optionally polyorganosiloxanes comprising no polyphenylene ether radicals by phase separation and washing to neutrality,

6) optionally followed by blending of the product from step 5 with further polyphenylene ether, preferably according to formula (IX), and subsequent devolatilization, in particular when polyorganosiloxane copolymers were produced with phenols and no polyphenylene ethers were present up to the end of step 5. If no further blending with further polyphenylene ether is desired, devolatilization is carried out immediately after step 5.

Instead of adding further polyphenylene ether immediately after step 5 the product mixture may also be isolated after step 5 and subsequently blended with further polyphenylene ether in a separate step, optionally in the melt or with the aid of a suitable solvent, for example in the context of the production process of a binder bath solution for producing glass fiber composites for copper-clad laminates. It is optionally also possible to additionally add other organic polymers distinct from polyphenylene ether, such as for example polystyrene, polyolefins, bismaleimides, Bismaleimide triazines, polybenzoxazines, cyanate ester resins or epoxy resins.

Production of the reactant initial charge according to step 1) may be effected by simple combination of the chlorosilanes of formula (I), optionally of the disiloxanes of formula (IV) and the polyphenylene ethers of formula (VII) and/or the phenols of formula (V) by successive dissolution/mixing of the individual components, wherein it is preferable to initially dissolve the polyphenylene ether/the phenols and subsequently add the chlorosilane(s) of formula (I) and optionally the disiloxanes(s) of formula (IV). The sequence of addition of the chlorosilane or the chlorosilanes of formula (I) and optionally the disiloxane or the disiloxanes of formula (IV) is discretionary.

Preferred aromatic solvents are toluene, xylene, as pure isomers or as isomer mixtures, or ethylbenzene and may be used alone or in admixture.

It is a characteristic of the process that no alcohols for stabilizing the resulting polyalkylsiloxanes against unwanted gelling are employed. The process also eschews the use of carboxylic esters which likewise counter unwanted gelling of the polyorganosiloxane by accelerating rapid transfer of the resulting initially hydrophilic and water-soluble polyorganosiloxane partial hydrolysate from the water phase into the organic phase. All other phase mediators are also eschewed in the synthesis.

This ensures that no alkoxy groups are formed on the polyorganosiloxane. The polyorganosiloxane has only OH groups as silanol groups, wherein these are present in small amounts of generally less than 1% by weight.

The chloride radicals of the chlorosilanes of formula (I) form hydrochloric acid during the reaction with water.

The water phase in step 2) may be selected such that it cannot completely absorb the resulting hydrochloric acid, with the result that hydrochloric acid fumes out as gas and may optionally be captured for recycling. However, the water phase may also be selected such that the resulting hydrochloric acid is completely dissolved therein and no hydrogen chloride fumes out. The configuration of the water phase is essentially determined by the apparatus used and the technical embodiment. If the formation of fuming hydrochloric acid cannot be tolerated from an apparatus point of the it is preferable to select the water phase such that a 5-30%, particularly preferably 10-30%, especially preferably 20-30%, aqueous hydrochloric acid solution is formed.

Mixing the chlorosilanes of formula (I) with phenol, substituted phenols or polyphenylene ethers in an anhydrous environment initially forms the corresponding condensation products of the respective chlorosilane with phenol, the substituted phenols or the polyphenylene ethers. These are Si—O—C bonded condensation products. The more chlorine atoms are present in the chlorosilanes of formula (I), the faster they react. That is to say a trichlorosilane reacts with an Si—CI bond more rapidly than a dichlorosilane, the latter in turn reacting more rapidly than a monochlorosilane. The mixture of different silanes preferably comprises the condensation products of phenol or the substituted phenols or the polyphenylene ethers with the most chlorine-substituted chlorosilane of formula (I).

It will be appreciated that condensation products of disiloxanes of formula (IV) and phenols of formula (V)/polyphenylene ethers of formula (VII) cannot be formed since no functional groups suitable therefor are present.

The reactant initial charge thus comprises a mixture of unaltered chlorosilanes of formula (I), chlorosilanes of formula (I) condensed with the phenols of formula (V) or the polyphenylene ethers of formula (VII), phenols of formula (V), polyphenylene ethers of formula (VII) and optionally disiloxanes of formula (IV) and an aromatic solvent in different relative proportions depending on the selected relative ratio of these components. The term reactant initial charge is to be understood as meaning this mixture.

It is preferable to employ a pH-neutral water initial charge in step 2) so that no acid is present in the water phase before step 3) is carried out. The reaction proceeds autocatalytically due to the resulting hydrochloric acid. A plurality of reactions occur. The chlorine atoms of the chlorosilanes of formula (I) eliminate HCl as a result of the reaction with water while simultaneously undergoing addition reaction with OH groups to afford silanols which, under the conditions of acid hydrolysis, are unstable and through formation of Si—O—Si bridges form polyorganosiloxanes. The same thing naturally occurs with the remaining chlorine atoms of the chlorosilanes of formula (I) which have previously reacted with phenols of formula (V)/polyphenylene ethers of formula (VII) in the reactant initial charge. The disiloxanes of formula (IV) are cleaved into monomers and likewise take part in the condensation reaction, wherein they are incorporated into the polyorganopolysiloxanes as terminal end units. They act as molecular weight regulators. The Si—O—C bonds of the condensation products of the chlorosilanes of formula (I) with phenols of formula (V) and the polyphenylene ethers of formula (VII) are cleaved under the hydrolytic conditions to establish a stable equilibrium between Si—O—C bond cleavage and condensation that under the selected conditions is on the side of the Si—O—C bond cleavage, with the result that only a stable proportion of intact Si—O—C bonds remains. The cleaved Si—O—C bonds form stable Si—O—Si bonds and also the OH-functional polyphenylene ethers. This occurs uniformly in the well-mixed reaction reactor and a homogeneous product mixture is therefore obtained.

In the process according to the invention the silicone phase forms a water-immiscible phase. This affords at the end of the reaction in step 4) a biphasic reaction mixture which is subsequently purified in step 5). These process steps for workup 5) may be carried out in any desired advantageous sequence, wherein the advantageousness is determined by the intermediately occurring properties of the silicone phase, such as for instance viscosity, phase configuration etc. Reference may here be made to the experience and procedures of the common knowledge prior art. The workup 5) is carried out for example by separation of the aqueous phase from the silicone phase, subsequent washing to neutrality of the silicone phase with neutral or basified water and subsequent distillation of the silicone phase. This purification, including devolatilization, concludes the process according to the invention. The basification of the washing water may be carried out for example by addition of sodium hydrogencarbonate, sodium hydroxide, ammonia, sodium methoxide or another base, preferably in the form of its salt. If the polyorganosiloxane contains Si—H groups, washing is preferably carried out with neutral water and not with basic water in order to avoid elimination of elemental hydrogen.

If insoluble solids have formed in the silicone phase they are removed by filtration through suitable filter media prior to distillation.

The process according to the invention affords liquid, optionally high-viscosity or solid compositions.

The compositions according to the invention are particularly suitable for use as binders for producing shaped articles having constant dielectric properties, in particular fiber composites. One fiber composite application for which they are particularly suitable relates to the production of copper-clad laminates of glass fiber composites for further production of printed circuit boards.

They may further be used in corrosion inhibiting compositions, in particular for use for corrosion inhibition at high temperature.

In addition, the compositions according to the invention may also be used for inhibiting corrosion of reinforcing steel in steel-reinforced concrete. Corrosion inhibiting effects in steel-reinforced concrete are achieved not only when the compositions according to the invention and compositions containing these are introduced into the concrete mixture before it is formed and cured but also when the compositions according to the invention and compositions containing these are applied to the surface of the concrete after the concrete has cured.

In addition to inhibiting corrosion of metals, the compositions according to the invention may also be used for manipulating further properties of compositions containing the compositions according to the invention or of solid articles or films obtained from compositions containing the compositions according to the invention, such as for example:
Controlling electrical conductivity and electrical resistance
Controlling the flow properties of a preparation
Controlling the gloss of a moist or cured film or of an object
Increasing weathering resistance
Increasing chemicals resistance
Increasing color stability
Reducing chalking tendency
Reducing or increasing the stick or slip friction of solid articles or films obtained from compositions containing compositions according to the invention
Stabilizing or destabilizing foam in the preparation containing the compositions according to the invention
Improving the adhesion of the preparation containing the compositions according to the invention to substrates,
Controlling filler and pigment wetting and dispersion behavior,
Controlling the rheological properties of the preparation containing the compositions according to the invention,
Controlling the mechanical properties, for example flexibility, scratch resistance, elasticity, extensibility, bendability, tear behavior, rebound behavior, hardness, density, tear propagation resistance, compression set, behavior at different temperatures, expansion coefficient, abrasion resistance and further properties such as thermal conductivity, flammability, gas permeability, resistance to water vapor, hot air, chemicals, weathering and radiation, sterilizability, of solid articles or films containing the compositions according to the invention or preparations containing said compositions,
controlling electrical properties, for example dielectric loss factor, dielectric strength, dielectric constant, tracking resistance, arc resistance, surface electrical resistance, specific dielectric strength,
flexibility, scratch resistance, elasticity, extensibility, bendability, tear behavior, rebound behavior, hardness, density, tear propagation resistance, compression set, behavior at different temperatures of solid articles or films obtainable from the preparation containing the compositions according to the invention.

Examples of applications in which the composition according to the invention may be employed to manipulate the properties described above are the production of coating compositions and impregnations and coatings and coverings obtainable therefrom on substrates, such as metal, glass, wood, mineral substrates, synthetic and natural fibers for production of textiles, carpets, floor coverings or other goods producible from fibers, leather, plastics, such as films, and moldings. With appropriate selection of the preparation components the compositions according to the invention may also be used in compositions as an additive for defoaming, flow promotion, hydrophobization, hydrophilization, filler and pigment dispersion, filler and pigment wetting, substrate wetting, promoting surface smoothness, reducing the stick or slip friction on the surface of the cured composition obtainable from the additized preparation. The compositions according to the invention may be incorporated into elastomer compositions in liquid form or in cured solid form. They may be used here for reinforcing or improving other performance properties, such as controlling transparency, heat resistance, yellowing tendency or weathering resistance.

All of the above symbols in the above formulae are in each case defined independently of one another. The silicon atom is tetravalent in all of the formulae.

### EXAMPLES

The processes and compositions according to the invention are hereinbelow described in examples. All percentages are percentages by weight. Unless otherwise stated all manipulations are performed at room temperature of 23° C. and at standard pressure (1.013 bar).

Unless otherwise stated all data for describing product properties apply at room temperature of 23° C. and at standard pressure (1.013 bar).

The apparatuses are commercially available laboratory apparatuses such as are commercially available from numerous apparatus manufacturers.

Ph represents a phenyl radical=C₆H₅—

Me represents a methyl radical=CH₃—. Me₂ accordingly represents two methyl radicals.

PPE represents polyphenylene ether.

HCl represents hydrogen chloride.

In the present text, substances are characterized by specifying data obtained by instrumental analysis. The underlying measurements are either performed according to publicly available standards or determined using specially developed methods. To ensure the clarity of the present teaching methods used are specified hereinbelow. In all examples the reported parts and percentages refer to weight unless otherwise stated.

### Viscosity:

Unless otherwise stated the viscosities are determined by rotational viscometry according to DIN EN ISO 3219. Unless otherwise stated all viscosity data apply at 25° C. and standard pressure of 1013 mbar.

### Refractive Index:

Unless otherwise stated the refractive indices are determined in the wavelength range of visible light at 589 nm at 25° C. and standard pressure of 1013 mbar according to the standard DIN 51423.

### Transmittance:

Transmittance is determined by UV VIS spectroscopy. The Analytik Jena Specord 200 instrument is suitable for example.

The employed measurement parameters are: Range: 190-1100 nm, step width: 0.2 nm, integration time: 0.04 s, measurement mode: step mode. The reference measurement(background) is performed first. A quartz plate secured to a sample holder (dimension of quartz plates: h×w about 6×7 cm, thickness about 2.3 mm) is placed into the sample beam path and measured against air.

This is followed by sample measurement. A quartz plate secured to the sample holder and having the sample applied to it—layer thickness of applied sample about 1 mm—is placed into the sample beam path and measured against air. Internal calculation versus the background spectrum gives the transmission spectrum of the sample.

### Molecular Compositions:

Molecular compositions are determined using nuclear magnetic resonance spectroscopy (for terminology see ASTM E 386: High-resolution nuclear magnetic resonance (NMR) spectroscopy: terms and symbols), by measuring the ¹H nucleus and the ²⁹Si nucleus.

### Description of ¹H NMR Measurement

Solvent: CDCl3, 99.8%d

Sample concentration: about 50 mg/1 ml CDCl3 in 5 mm NMR tubes

Measurement without addition of TMS, spectral referencing of residual CHCl3 in CDCl3 at 7.24 ppm

Spectrometer: Bruker Avance I 500 or Bruker Avance HD 500

Probe:5 mm BBO probe or SMART probe (Bruker)

Measurement parameters:

$$Pulprog = zg30$$

$$TD = 64 k$$

$$NS = 64 or 128 ( depending on probe sensitivity )$$

$$SW = 20.6 ppm$$

$$AQ = 3.17 s$$

$$D 1 = 5 s$$

$$SFO 1 = 500.13 MHz$$

$$O 1 = 6.175 ppm$$

Processing parameters:

$$SI = 32 k$$

$$WDW = EM$$

$$LB = 0.3 Hz$$

Depending on the employed spectrometer type individual adjustments to the measurement parameters may be necessary.

### Description of ²⁹Si NMR Measurement

Solvent: C6D6 99.8%d/CCl4 1:1 v/v with 1% by weight of Cr(acac)₃ as relaxation reagent

Sample concentration: about 2 g/1.5 ml of solvent in 10 mm NMR tubes

Spectrometer: Bruker Avance 300

Probe: 10 mm 1H/13C/15N/29Si glass-free QNP probe (Bruker)

Measurement Parameters:

$$Pulprog = zgig 60$$

$$TD = 64 k$$

$$NS = 1024 ( depending on probe sensitivity )$$

$$SW = 200 ppm$$

$$AQ = 2.75 s$$

$$D 1 = 4 s$$

$$SFO 1 = 300.13 MHz$$

$$O 1 = - 50 ppm$$

### Processing Parameters:

$$SI = 64 k$$

$$WDW = EM$$

$$LB = 0.3 Hz$$

Depending on the employed spectrometer type individual adjustments to the measurement parameters may be necessary.

### Molecular Weight Distributions:

Molecular weight distributions are determined as the weight-average Mw and the number-average Mn using the methods of gel permeation chromatography (GPC) and size exclusion chromatography (SEC) with a polystyrene standard and a refractive index detector (RI detector). Unless otherwise stated THF is used as eluent and DIN 55672-1 is followed. Polydispersity is the quotient Mw/Mn.

### Glass Transition Temperatures:

The glass transition temperature is determined by differential scanning calorimetry, DSC, according to DIN 53765, holed crucible, heating rate 10 K/min.

### Determination of Particle Size:

The particle sizes were determined by the method of dynamic light scattering (DLS) using the zeta potential.

The following auxiliary materials and reagents were used for the determination:

Polystyrene cuvettes of 10×10×45 mm, Pasteur pipettes for single use, ultrapure water.

The sample to be measured is homogenized and filled into the measuring cuvette avoiding bubble formation.

After an equilibration time of 300 seconds high resolution measurement is carried out at 25° C. with automatic measuring time adjustment.

The reported values always refer to the D(50) value. D(50) is to be understood as meaning the volume-averaged particle diameter at which 50% of all measured particles have a volume-average diameter smaller than the specified value D(50).

### Determination of Dielectric Properties: Df, Dk

Determination of dielectric properties is carried out according to IPC TM 650 2.5.5.13 using a Keysight/Agilent E8361A network analyzer by the split-cylinder resonator method at 10 GHz.

### Microscopy Procedure:

Microstructure and nanostructure were characterized by optical microscopy and by transmission electron microscopy respectively.

### Optical Microscopy:

Sample preparation: 1 droplet of sample (undiluted) on slide; covered with coverslip Instrument: LEICA DMRXA2 with LEICA DFC420 CCD camera (2592×1944 pixels) Imaging: transmitted light—interference contrast, different magnification levels

### Transmission Electron Microscopy:

Sample preparation: 1 droplet of sample (dilution 1:20, adjustment necessary if required) on coated TEM grid; addition of contrast agent if required; drying at RT

Instrument: ZEISS LIBRA 120 with Sharp Eye CCD camera (1024×1024 Pixel)

Imaging: excitation voltage 120 kV; TEM brightfield; various magnification levels

### Example 1: Production of an Inventive Preparation by Reaction of a Mixture of Phenyltrichlorosilane, Dimethylchlorosilane, Vinyldimethylchlorosilane and the Polyphenylene Ether of Formula (X)

670.65 g of demineralized water are initially charged in a 4 | four-necked flask fitted with a propeller stirrer, reflux condenser, dropping funnel and thermometer. 128.97 g of the polyphenylene ether of formula (X)

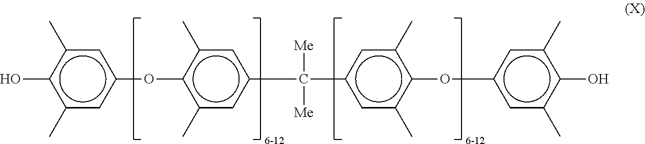

are dissolved in 257.94 g of toluene at 23° C. To this solution are successively added 75 g (0.63 mol) of vinyldimethylchlorosilane, 60.5 g (0.63 mol) of dimethylchlorosilane and 380.38 g (1.78 mol) of phenyltrichlorosilane. The resulting mixture is stirred at 23°C. for 14 hours. By ¹H NMR spectroscopy the change in the signal for the proton of the phenolic OH group is used to determine a conversion with the chlorosilane mixture of 64%, i.e. the intensity of the signal has reduced by this magnitude. This observation is in agreement with the analogous procedure and observations such as are described in US 2020/0285575.

The mixture is then transferred into the dropping funnel.

The mixture from the dropping funnel is then uniformly added to the stirred water initial charge over 2 hours. The temperature of the mixture increases exothermically. A small amount of gas evolution is observed, the gas being hydrochloric acid. The gaseous hydrochloric acid is diverted from the reaction vessel and absorbed in an aqueous initial charge. The majority of the hydrochloric acid formed immediately dissolves in the water present and over the course of the ongoing reaction forms a concentrated aqueous hydrochloric acid solution.

The addition rate is adapted so as not to exceed 50° C.

Once addition is complete the mixture is stirred for a further 15 minutes, 1500 ml of acetone are added and the stirrer is then stopped. This results in formation of two phases, a dark organic phase and a lighter-colored aqueous phase. The aqueous phase highly acidified with hydrochloric acid is the lower phase and is discharged. The organic phase is washed to neutrality. To this end, 1000 ml of 10% sodium chloride solution are added to the organic phase, the mixture is stirred for 30 minutes and the stirrer is then stopped. The phases separate and the aqueous phase is the lower phase. This is discharged. The washing operation is repeated twice in total. The residual content of hydrochloric acid in the organic phase is determined by titrimetry. If the hydrochloric acid content of the organic phase is above 20 ppm, washing is continued until it falls below this threshold and a target range between 0 and 20 ppm of HCl is established.

The organic phase is dark-brown and clear. The organic solvents are removed under reduced pressure (20 mbar) at elevated temperature (175° C.). The devolatilization is complete after 1 hour. The residual solvent content is 1300 ppm of toluene. A brown solid which is soluble in toluene and clear and transparent in thin layers is obtained (=preparation 1.1).

It was found by transmission electron microscopy (TEM) that no separate domains of polyorganosiloxane and polyphenylene ether are formed in thin films. The two preparation components are entirely homogeneously miscible.

The obtained product mixture is analytically described by nuclear magnetic resonance spectroscopy (NMR) and by size exclusion chromatography (SEC):

Since no alkoxy-imparting reagents were used, the obtained product is free from alkoxy groups.

The following molecular weights were determined by SEC (eluent toluene): Mw=3347 g/mol, Mn=1554 g/mol, polydispersity PD=2.15.

According to ²⁹Si NMR the molar composition of the silicon-containing proportion of the preparation is:

Me₂Si(H)O_{1/2}: 18.11%

Me₂Si(Vi)O_{1/2}: 19.60

PhSi(OR)₂O_{1/2}: 1.39%

PhSi(OR)O_{2/2}: 22.50%

PhSiO_{3/2}: 38.40%

In this case the radical R represents either hydrogen or the polyphenylene ether radical that results from the polyphenylene ether (X) by abstraction of the phenolic H atom and addition reaction onto a silicon atom.

Evaluation of the ¹H-NMR spectrum reveals that the mixture contains 25.3 mol % of the polyphenylene ether of formula (X), wherein the intensity of the phenolic OH signal makes it possible to determine that 5.2% of the polyphenylene ether amount present (25.3 mol % assumed as 100%, of which 5.2% is calculated) is silicon-bonded, i.e. 1.3 mol %.

50 g of the obtained preparation are dissolved in 200 g of a solution of 75 g of the polyphenylene ether (X) in 125 g of toluene and stirred for 30 minutes before the solvent is removed at elevated temperature (175° C.) and reduced pressure (20 mbar). This affords a brown solid product (=preparation 1.2) which appears transparent in thin layers and whose homogeneous compatibility is in turn demonstrable in the same way as described above for the reaction product of this example.

In the same way as described above a preparation of 50 g of the reaction product from this example is produced with 75 g of a polyphenylene ether of formula (XI).

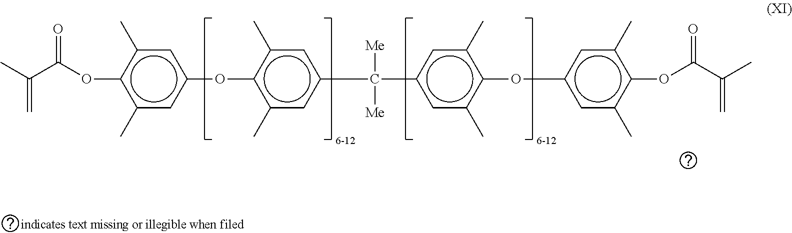

This preparation is also brown, transparent in thin films and, according to TEM, completely homogeneous (=preparation 1.3).

The three compositions 1.1, 1.2 and 1.3 are cured by admixing the respective preparation with 1% by weight, based on the mass of the preparation, of 2,5-bis(tert-butylperoxy)-2,5-dimethylhexane and mixing and milling the resulting mixture in a coffee grinder. The preparation in question is placed in an aluminum dish and cured in a heating cabinet heated to 180°C. for 2 hours. A clear brown solid which is no longer soluble in toluene is obtained in each case.

DSC gives the following values for the glass transition temperatures of the three cured compositions:

1.1: 97° C.

1.2: 117° C.

1.3: 139° C.

For comparison the glass transition temperature of the polyphenylene ethers (X) and (XI) is:

$${T}_{g} ( X ) = 147 ° C .$$

$${T}_{g} ( XI ) = 164 ° C .$$

The dielectric loss factor and the dielectric constant of the three cured compositions are determined according to IPC TM 650 2.5.5.13 using a Keysight Agilent E8361A network analyzer. This gives the following values:

| Material | D_{f} (10 GHz) | Dₖ (10 GHz) |
|---|---|---|
| Preparation 1.1 | 0.0043 | 2.73 |
| Preparation 1.2 | 0.0041 | 2.70 |
| Preparation 1.3 | 0.0039 | 2.64 |
| PPE (X) | 0.0032 | 2.67 |
| PPE (XI) | 0.0025 | 2.33 |

### Example 2: Production of an Inventive Preparation by Reaction of a Mixture of Phenyltrichlorosilane, Dimethylchlorosilane, Vinyldimethylchlorosilane and a Polyphenylene Ether of Formula (X)

The procedure corresponds to that of example 1 with the following exceptions:

The following substances are employed in the following amounts:

Demineralized water initial charge: 1198.8 g

Vinyldimethylchlorosilane: 240 g (2.0 mol)

Dimethylchlorosilane: 120 g (1.24 mol)

Phenyltrichlorosilane: 540 g (2.52 mol)

Toluene: 449.64 g

PPE (X): 225 g

Devolatilization from the solvent takes 1.5 hours.

The obtained product has the following analytical properties:

No alkoxy groups are present. The following molecular weights were determined by SEC (eluent toluene): Mw=3238 g/mol, Mn=1218 g/mol, polydispersity PD=2.66.

According to ²⁹Si NMR the molar composition of the silicon-containing proportion of the preparation is:

Me₂Si(H)O_{1/2: 20.25}%

Me₂Si(Vi)O_{1/2: 21.75}%

PhSi(OR)₂O_{1/2}: 1.64%

PhSi(OR)O_{2/2}: 22.7%

PhSiO_{3/2}: 33.4%

In this case the radical R represents either hydrogen or the polyphenylene ether radical that results from the polyphenylene ether (X) by abstraction of the phenolic H atom and addition reaction onto a silicon atom.

Evaluation of the ¹H-NMR spectrum reveals that the mixture contains 26.8 mol % of the polyphenylene ether of formula (X), wherein the intensity of the phenolic OH signal makes it possible to determine that 6.8% of the polyphenylene ether amount present (26.8 mol % assumed as 100%, of which 7.8% is calculated) is silicon-bonded, i.e. 1.8 mol %

Compositions 2.2 and 2.3 are produced from the reaction product (=preparation 2.1) in the same way as described in example 1.

All compositions obtained are brown solids which are clear in thin layers and according to TEM analysis are completely homogeneous.

DSC gives the following values for the glass transition temperatures of the three cured compositions:

2.1: 76° C.

2.2: 103° C.

2.3: 121° C.

The dielectric loss factor and the dielectric constant of the three cured compositions are determined according to IPC TM 650 2.5.5.13 using a Keysight Agilent E8361A network analyzer. This gives the following values:

| Material | D_{f} (10 GHz) | Dₖ (10 GHz) |
|---|---|---|
| Preparation 2.1 | 0.0043 | 2.71 |
| Preparation 2.2 | 0.0041 | 2.69 |
| Preparation 2.3 | 0.0040 | 2.69 |

### Example 3: Production of an Inventive Preparation by Reaction of a Mixture of Phenyltrichlorosilane, Dimethylchlorosilane and a Polyphenylene Ether of Formula (X)

The procedure corresponds to that of example 1 with the following exceptions:

The following substances are employed in the following amounts:

Demineralized water initial charge: 585.1 g

Dimethylchlorosilane: 21.5 g (0.22 mol)

Phenyltrichlorosilane: 428.6 g (2.00 mol)

Toluene: 225 g

PPE (X): 112.5 g

Devolatilization from the solvent takes 1.0 hours.

The obtained product has the following analytical properties:

No alkoxy groups are present. The following molecular weights were determined by SEC (eluent toluene): Mw=3364 g/mol, Mn=1558 g/mol, polydispersity PD=2.16.

According to ²⁹Si NMR the molar composition of the silicon-containing proportion of the preparation is:

Me₂Si(H)O_{1/2}: 8.38%

PhSi(OR)₂O_{1/2}: 1.72%

PhSi(OR)O_{2/2}: 35.3%

PhSiO_{3/2}: 54.6%

In this case the radical R represents either hydrogen or the polyphenylene ether radical that results from the polyphenylene ether (X) by abstraction of the phenolic H atom and addition reaction onto a silicon atom.

Evaluation of the ¹H-NMR spectrum reveals that the mixture contains 24.8 mol % of the polyphenylene ether of formula (X), wherein the intensity of the phenolic OH signal makes it possible to determine that 5.7% of the polyphenylene ether amount present (24.8 mol % assumed as 100%, of which 5.7% is calculated) is silicon-bonded, i.e. 1.4 mol %

Compositions 3.2 and 3.3 are produced from the reaction product (=preparation 3.1) in the same way as described in example 1.

All compositions obtained are brown solids which are clear in thin layers and according to TEM analysis are completely homogeneous.

DSC gives the following values for the glass transition temperatures of the three cured compositions:

3.1: 107° C.

3.2: 134° C.

3.3: 151° C.

The dielectric loss factor and the dielectric constant of the three cured compositions is determined according to IPC TM 650 2.5.5.13 using a Keysight Agilent E8361A network analyzer. This gives the following values:

| Material | D_{f} (10 GHz) | Dₖ (10 GHz) |
|---|---|---|
| Preparation 3.1 | 0.0045 | 2.79 |
| Preparation 3.2 | 0.0041 | 2.75 |
| Preparation 3.3 | 0.0040 | 2.73 |

### Example 4: Production of an Inventive Preparation by Reaction of a Mixture of Phenyltrichlorosilane, Vinyldimethylchlorosilane and the Polyphenylene Ether of Formula (X)

The procedure corresponds to that of example 1 with the following exceptions:

The following substances are employed in the following amounts:

Demineralized water initial charge: 1198.8 g

Vinyldimethylchlorosilane: 30 g (0.25 mol)

Phenyltrichlorosilane: 428.6 g (2.00 mol)

Toluene: 225 g

PPE (X): 112.5 g

Devolatilization from the solvent takes 1.5 hours.

The obtained product has the following analytical properties:

No alkoxy groups are present. The following molecular weights were determined by SEC (eluent toluene): Mw=3549 g/mol, Mn=1317 g/mol, polydispersity PD=2.69.

According to ²⁹Si NMR the molar composition of the silicon-containing proportion of the preparation is:

Me₂Si(Vi)O_{1/2}: 9.27%

PhSi(OR)₂O_{1/2}: 1.91%

PhSi(OR)O_{2/2}: 34.8%

PhSiO_{3/2}: 54.0%

In this case the radical R represents either hydrogen or the polyphenylene ether radical that results from the polyphenylene ether (X) by abstraction of the phenolic H atom and addition reaction onto a silicon atom.

Evaluation of the ¹H-NMR spectrum reveals that the mixture contains 25.6 mol % of the polyphenylene ether of formula (X), wherein the intensity of the phenolic OH signal makes it possible to determine that 6.0% of the polyphenylene ether amount present (25.6 mol % assumed as 100%, of which 6.0% is calculated) is silicon-bonded, i.e. 1.5 mol %

Compositions 4.2 and 4.3 are produced from the reaction product (=preparation 4.1) in the same way as described in example 1.

All compositions obtained are brown solids which are clear in thin layers and according to TEM analysis are completely homogeneous.

DSC gives the following values for the glass transition temperatures of the three cured compositions:

4.1: 114° C.

4.2: 141° C.

4.3: 159° C.

The dielectric loss factor and the dielectric constant of the three cured compositions is determined according to IPC TM 650 2.5.5.13 using a Keysight Agilent E8361A network analyzer. This gives the following values:

| Material | D_{f} (10 GHz) | Dₖ (10 GHz) |
|---|---|---|
| Preparation 4.1 | 0.0041 | 2.67 |
| Preparation 4.2 | 0.0035 | 2.61 |
| Preparation 4.3 | 0.0032 | 2.60 |

Example 5: Production of an Inventive Preparation by Reaction of a Mixture of Phenyltrichlorosilane, Vinyldimethylchlorosilane and 2,6-dimethylphenol

The procedure corresponds to that of example 1 with the following exceptions:

The following substances are employed in the following amounts:

Demineralized water initial charge: 1200.0 g

Vinyldimethylchlorosilane: 240 g (2.0 mol)

Dimethylchlorosilane: 120 g (1.24 mol)

Phenyltrichlorosilane: 540 g (2.52 mol)

Toluene: 449.64 g

2,6-Dimethylphenol: 122 g

Devolatilization from the solvent takes 1.5 hours.

The obtained product has the following analytical properties:

No alkoxy groups are present. The following molecular weights were determined by SEC (eluent toluene): Mw=2338 g/mol, Mn=1278 g/mol, polydispersity PD=1.89. According to ²⁹Si NMR the molar composition of the silicon-containing proportion of the preparation is:

Me₂Si(H)O_{1/2}: 20.52%

Me₂Si(Vi)O_{1/2}: 21.98%

PhSi(OR)₂O_{1/2}: 2.36%

PhSi(OR)O_{2/2}: 21.9%

PhSiO_{3/2}: 33.24%

In this case the radical R represents either hydrogen or the 2,6-dimethylphenol radical that results from 2,6-dimethylphenol by abstraction of the phenolic H atom and addition reaction onto a silicon atom. A total of 1.37% by weight of silanol groups are present, as is apparent from the ¹H-NMR spectrum.

Evaluation of the ¹H-NMR spectrum reveals that the mixture contains 23.4 mol % of 2,6-dimethylphenols, wherein the intensity of the phenolic OH signal makes it possible to determine that 5.9% of the dimethylphenol amount present (23.4 mol % assumed as 100%, of which 5.9% is calculated) is silicon-bonded, i.e. 1.4 mol %.

Compositions 5.2 and 5.3 are produced from the reaction product (=preparation 5.1) in the same way as described in example 1.

All compositions obtained are yellowish solids which are clear in thin layers and according to TEM analysis are completely homogeneous.

DSC gives the following values for the glass transition temperatures of the three cured compositions:

2.1: 56° C.

2.2: 82° C.

2.3: 101° C.

The dielectric loss factor and the dielectric constant of the three cured compositions is determined according to IPC TM 650 2.5.5.13 using a Keysight Agilent E8361A network analyzer. This gives the following values:

| Material | D_{f} (10 GHz) | Dₖ (10 GHz) |
|---|---|---|
| Preparation 5.1 | 0.0042 | 2.69 |
| Preparation 5.2 | 0.0039 | 2.67 |
| Preparation 5.3 | 0.0036 | 2.64 |

### Comparative Example 1: Production of a Noninventive Preparation by Reaction of a Mixture of Methyltrichlorosilane and Vinyldimethylchlorosilane and of the Polyphenylene Ether of Formula (X)

The procedure corresponds to that of example 1 with the following exceptions:

The following substances are employed in the following amounts:

Demineralized water initial charge: 1198.8 g

Vinyldimethylchlorosilane: 30 g (0.25 mol)

Methyltrichlorsilane: 299 g (2.00 mol)

Toluene: 225 g

PPE (X): 112.5 g

Devolatilization from the solvent takes 1.0 hours.

The obtained product has the following analytical properties:

No alkoxy groups are present. The following molecular weights were determined by SEC (eluent toluene): Mw=3658 g/mol, Mn=1058 g/mol, polydispersity PD=3.46.

The obtained product is brown and does not give clear films but rather affords cloudy, opaque films.

According to ²⁹Si NMR the molar composition of the silicon-containing proportion of the preparation is:

Me₂Si(Vi)O_{1/2}: 8.99%

MeSi(OR)₂O_{1/2}: 1.52%

MeSi(OR)O_{2/2}: 30.8%

MeSiO_{3/2}: 58.7%

In this case the radical R represents either hydrogen or the polyphenylene ether radical that results from the polyphenylene ether (X) by abstraction of the phenolic H atom and addition reaction onto a silicon atom. In principle, two hydrogen atoms can be abstracted from the di-OH-terminated polyphenylene ether (X). However, due to the relatively small amount of silicon-bonded polyphenylene ether radicals relative to the total amount of polyphenylene ether this may be considered unlikely and therefore preferably or exclusively only one phenolic hydrogen atom is abstracted for radical formation. The same situation should apply to all examples described here and not be limited to this specific example.

Evaluation of the ¹H-NMR spectrum reveals that the mixture contains 27.0 mol % of the polyphenylene ether of formula (X), wherein the intensity of the phenolic OH signal makes it possible to determine that 7.8% of the polyphenylene ether amount present (27.0 mol % assumed as 100%, of which 7.8% is calculated) is silicon-bonded, i.e. 2.1 mol %

Compositions VB 1.2 and VB 1.3 are produced from the reaction product (=preparation VB 1.1) in the same way as described in example 1.

All obtained compositions are brown solids which, however, are cloudy and unclear in thin layers and according to TEM analysis form clearly distinguishable silicone domains and regions of organic polymer. The compositions are thus inhomogeneous on account of the incompatibility of the components mixed with one another.

DSC gives the following values for the glass transition temperatures of the three cured compositions:

VB 1.1: 89° C.

VB 1.2: 111° C.

VB 1.3: 131° C.

The dielectric loss factor and the dielectric constant of the three cured compositions is determined according to IPC TM 650 2.5.5.13 using a Keysight Agilent E8361A network analyzer. This gives the following values:

| Material | D_{f} (10 GHz) | Dₖ (10 GHz) |
|---|---|---|
| Preparation VB 1.1 | 0.0054 | 2.89 |
| Preparation VB 1.2 | 0.0052 | 2.86 |
| Preparation VB 1.3 | 0.0052 | 2.85 |

Comparative Example 2: Production of a Noninventive Preparation by Reaction of Methyltrichlorosilane with Ethanol in the Presence of the Polyphenylene Ether of Formula (X)

448.44 g (3.0 mol) of methyltrichlorosilane are initially charged in a 4 | four-necked flask fitted with a propeller stirrer, reflux condenser, dropping funnel and thermometer. At a starting temperature of 23° C. a mixture of 313.91 g of ethanol and 31.39 g of demineralized water is added dropwise to this initial charge over 10 minutes. This causes evolution of hydrogen chloride gas which partially dissolves in the water phase and is partially obtained in gaseous form. The hydrogen chloride obtained in gaseous form is discharged from the reaction vessel and collected and neutralized in a washing bottle supplied with a 10% aqueous sodium hydroxide solution.

A solution of 86.00 g of the polyphenylene ether (X) in 462.75 g of toluene is rapidly added to the obtained mixture in the reaction vessel. 111.06 g of demineralized water are added to this initial charge over 35 minutes. The temperature of the mixture in the reaction vessel increases from 23.9° C. to 50.8° C. After stirring for 30 minutes, an additional 666.36 g of water are added over 5 minutes, the preparation is thoroughly mixed and then 1 I of acetone is added. After renewed mixing the stirring is stopped. After being left to stand for one hour the lower phase is separated. It consists of hydrochloric acid, water, ethanol and acetone.

The remaining organic phase is admixed with 2.58 g of activated carbon, 2.06 g of sodium hydrogencarbonate and 3.40 g of filtration aid DICALITE® Perlite Filterhilfe 478 (Süd Chemie) and the mixture is filtered via a suction filter with a Seitz K 100 filter sheet. A clear, brown solution is obtained.

The solvent is then distilled off completely under reduced pressure. A vacuum of 20 mbar at 175° C. is finally achieved. The remaining hot liquid resin residue is poured onto a Teflon® sheet and allowed to cool. A solid toluene-soluble product (=preparation VB 2.1) is obtained.

The obtained product mixture is analytically described by nuclear magnetic resonance spectroscopy (NMR) and by size exclusion chromatography (SEC):

The residual solvent content is 1243 ppm of toluene.

The obtained product is brown and does not give clear films but rather affords cloudy, opaque films.

According to ¹H NMR spectroscopy determination 6.4% by weight of ethoxy groups and 1.2% by weight silanol groups present.

The following molecular weights were determined by SEC (eluent toluene): Mw=6583 g/mol, Mn=4056 g/mol, polydispersity PD=1.62.

According to ²⁹Si NMR the molar composition of the silicon-containing proportion of the preparation is:

MeSi(OR)_{201/2: 4.5}%

MeSi(OR)O_{2/2: 33.8}%

MeSiO_{3/2: 61.7}%

In this case the radical R represents either hydrogen, an ethyl radical or the polyphenylene ether radical that results from the polyphenylene ether (X) by abstraction of the phenolic H atom and addition reaction onto a silicon atom.

Evaluation of the ¹H-NMR spectrum reveals that the mixture contains 24.3 mol % of the polyphenylene ether of formula (X), wherein the intensity of the phenolic OH signal makes it possible to determine that 6.3% of the polyphenylene ether amount present (24.3 mol % assumed as 100%, of which 6.3% is calculated) is silicon-bonded, i.e. 1.5 mol %

Compositions VB 2.2 and VB 2.3 are produced from the reaction product (=preparation VB 2.1) in the same way as described in example 1.

All obtained compositions are brown solids which, however, are cloudy and unclear in thin layers and according to TEM analysis form clearly distinguishable silicone domains and regions of organic polymer. The compositions are thus inhomogeneous on account of the incompatibility of the components mixed with one another.

DSC gives the following values for the glass transition temperatures of the three cured compositions (curing at 230° C. for 2 hours):

VB 2.1: 171° C.

VB 1.2: 183° C.

VB 1.3: 191° C.

In the case of these compositions it is apparent that increased bubble formation occurs during curing and at layer thicknesses of more than 0.5 mm in thickness said bubbles can no longer be completely removed even with additional measures such as vacuum pressing. These air bubbles are attributed to the condensation of the remaining ethoxy groups which, during formation of siloxane bonds, eliminate ethanol which is obtained in gaseous form at the curing temperature. With increasing viscosity during curing these gas bubbles can no longer be removed from the test specimens and therefore only thin films are producible bubble-free under the curing conditions specified here. In addition, even in thin films renewed thermal stress through heating to 200° C. causes the formation of bubbles which expand the test specimen into a solid foam. Condensation is a slow process where the ethoxy groups present react only slowly, so that not all ethoxy groups present undergo complete reaction within the specified curing time of 2 h. The risk of subsequent elimination of further ethanol is thus unavoidable.

The dielectric loss factor and the dielectric constant of the three cured compositions is determined according to IPC TM 650 2.5.5.13 using a Keysight Agilent E8361A network analyzer. This gives the following values:

| Material | D_{f} (10 GHz) | Dₖ (10 GHz) |
|---|---|---|
| Preparation VB 2.1 | 0.0062 | 2.77 |
| Preparation VB 2.2 | 0.0054 | 2.83 |
| Preparation VB 3.3 | 0.0051 | 2.78 |

Comparative Example 3: Production of a Noninventive Preparation by Reaction of a Mixture of Phenyltrichlorosilane and Vinyldimethylchlorosilane with Ethanol in the Presence of the Polyphenylene Ether of Formula (X)

The procedure corresponds to that of comparative example 2 with the following exceptions:

The following substances are employed in the following amounts:

Vinyldimethylchlorosilane: 30 g (0.25 mol)

Phenyltrichlorosilane: 448.44g (2,12 mol)

The obtained product mixture is analytically described by nuclear magnetic resonance spectroscopy (NMR) and by size exclusion chromatography (SEC).

The residual solvent content is 873 ppm of toluene.

Ethoxy groups are present in an amount of 5.1% by weight determined by ¹H NMR.

The following molecular weights were determined by SEC (eluent toluene): Mw=3997 g/mol, Mn=1658 g/mol, polydispersity PD=2.41.

The obtained product is brown and gives clear, thin and transparent films.

According to ²⁹Si NMR the molar composition of the silicon-containing proportion of the preparation is:

Me₂Si(Vi)O_{1/2: 6.38}%

PhSi(OR)_{2012: 2.39}%

PhSi(OR)O_{2/2: 35.97}%

PhSiO_{3/2: 55.26}%

In this case the radical R represents either hydrogen, an ethyl radical or the polyphenylene ether radical that results from the polyphenylene ether (X) by abstraction of the phenolic H atom and addition reaction onto a silicon atom. The total amount of silanol groups was determined as 3.21% by weight by ¹H-NMR.

Evaluation of the ¹H-NMR spectrum reveals that the mixture contains 22.6 mol % of the polyphenylene ether of formula (X), wherein the intensity of the phenolic OH signal makes it possible to determine that 6.8% of the polyphenylene ether amount present (22.6 mol % assumed as 100%, of which 6.8% is calculated) is silicon-bonded, i.e. 1.5 mol %

Compositions VB 3.2 and VB 3.3 are produced from the reaction product (=preparation VB 3.1) in the same way as described in example 1.

All compositions obtained are brown solids which are clear in thin layers and according to TEM analysis do not form any distinguishable silicone domains and regions of organic polymer. The compositions are thus homogeneous.

DSC gives the following values for the glass transition temperatures of the three cured compositions:

VB 1.1: 181° C.

VB 1.2: 191° C.

VB 1.3: 202° C.

The dielectric loss factor and the dielectric constant of the three cured compositions are determined according to IPC TM 650 2.5.5.13 using a Keysight Agilent E8361A network analyzer. This gives the following values:

| Material | D_{f} (10 GHz) | Dₖ (10 GHz) |
|---|---|---|
| Preparation VB 3.1 | 0.0059 | 2.88 |
| Preparation VB 3.2 | 0.0054 | 2.89 |
| Preparation VB 3.3 | 0.0051 | 2.83 |

In the case of these compositions it is apparent that increased bubble formation occurs during curing and at layer thicknesses of more than 0.5 mm in thickness said bubbles can no longer be completely removed even with additional measures such as vacuum pressing. These air bubbles are attributed to the condensation of the remaining ethoxy groups which, during formation of siloxane bonds, eliminate ethanol which is obtained in gaseous form at the curing temperature. With increasing viscosity during curing these gas bubbles can no longer be removed from the test specimens and therefore only thin films are producible bubble-free under the curing conditions specified here. In addition, even in thin films renewed thermal stress through heating to 200° C. causes the formation of bubbles which expand the test specimen into a solid foam. Condensation is a slow process where the ethoxy groups present react only slowly, so that not all ethoxy groups present undergo complete reaction within the specified curing time of 2 h. The risk of subsequent elimination of further ethanol is thus unavoidable.

### Comparative Example 4:

### Production of a Vinyl-functional Methylphenyl Resin According to the Procedure of Production Example 3 in US 2018/0220530

Production example 3 in US 2018/0220530 contains no indication of the relative amounts of the raw materials employed. Accordingly, like all other production examples of US 2018/0220530, this production example likewise does not disclose a specific resin but merely specifies a general procedure. It should be noted here that the production examples of US 2018/0220530 always refer to the raw material triethylphenyl silicate which is added dropwise. Since the trethylphenylsilicate units always form T units in the resin this description is clearly incorrect. A silicate, in this case an ester of orthosilicic acid, can after hydrolysis and condensation only ever form a Q unit, as is readily understood by a person skilled in the art, since a silicate has the feature that the silicon atom is surrounded by 4 oxygen atoms which may optionally be differently substituted. In the course of hydrolysis all four of these alkoxy substituents may be eliminated, whereupon the condensation leads to said Q units via intermediate formation of silanol intermediates. This process is well-known from the synthesis of the so-called MQ resins. In this context reference is made to production example 2 of US 2018/0220530, where the Q unit is produced from tetraethyl orthosilicate in precisely this manner. Production example 2 in US 2016/0244610 also utilizes this procedure.

Since production example 3 in US 2018/0220530 produces a T unit it is thus clear that triethylphenylsilane, which can form such a T unit, is meant.

Following the procedure of production example 3 of US 2018/0220530, the following raw materials were reacted with one another in the specified amounts:

Divinyltetramethyldisiloxane: 69.75 g (0.375 mol)

Phenyltriethoxysilane: 240.0 g (1.5 mol)

Dimethyldiethoxysilane: 148.0 g (1.0 mol)

Aqueous hydrochloric acid, 20%: 0.916 g corresponds to 400 ppm of HCl based on the employed amount of silicone which is a customary amount of HCl known to those skilled in the art from numerous pieces of prior art as a condensation catalyst for such condensation tasks in a stirred reactor.

Demineralized water: 300 g

Ethanol: 35 g

Toluene: 400 g

250 g of water were added for each of the washes. Washing with water was carried out twice. Thereafter, the residual HCl content was below 20 ppm.

The obtained product mixture is analytically described by nuclear magnetic resonance spectroscopy (NMR) and by size exclusion chromatography (SEC).

The residual solvent content is 674 ppm of toluene.

According to ¹H NMR, 3.8% by weight of ethoxy groups are present. The following molecular weights were determined by SEC (eluent toluene): Mw=2470 g/mol, Mn=1789 g/mol, polydispersity PD=1.38.

The obtained product is colorless and clear.

According to ²⁹Si NMR the molar composition of the silicon-containing proportion of the preparation is:

Me₂Si(Vi)O_{1/2}: 25.23%

Me₂Si(OR)O_{1/2}: 1.39%

Me₂SiO_{2/2}: 29.01%

PhSi(OR)₂O_{1/2}: 5.92%

PhSi(OR)O_{2/2}: 10.09%

PhSiO_{3/2}: 28.36%

In this case, the radical R represents either hydrogen or an ethyl radical. The amount of silanol groups is 3.1% by weight according to ¹H NMR.

The proportion of phenyl radicals in the Si—C-bonded hydrocarbon radicals is 24.5 mol %, the proportion of vinyl radicals is 14.0 mol % and the proportion of methyl radicals is 61.5 mol %.

In the same way as described in example 1 the reaction product is used to produce compositions with the polyphenylene ethers of formula (X) and (XI) which are referred to as VB 4.2 und VB 4.3 according to the nomenclature of example 1.

The obtained compositions are brown solids which are cloudy and opaque in thin layers and according to TEM analysis form clearly distinguishable silicone domains and separate regions of polyorganosiloxane and organic polymer. The compositions are thus inhomogeneous.

DSC gives the following values for the glass transition temperatures of the three cured compositions:

Polyorganosiloxane: 87° C.

VB 4.2: 117° C.

VB 4.3: 142° C.

The dielectric loss factor and the dielectric constant of the pure resin and the two cured compositions are determined according to IPC TM 650 2.5.5.13 using a Keysight Agilent E8361A Network Analyzer. This gives the following values:

| Material | D_{f} (10 GHz) | Dₖ (10 GHz) |
|---|---|---|
| Polyorganosiloxane | 0.0054 | 2.97 |
| Preparation VB 3.2 | 0.0052 | 2.89 |
| Preparation VB 3.3 | 0.0051 | 2.83 |

In the case of these compositions it is apparent that increased bubble formation occurs during curing and at layer thicknesses of more than 0.5 mm in thickness said bubbles can no longer be completely removed even with additional measures such as vacuum pressing. These air bubbles are attributed to the condensation of the remaining ethoxy groups which, during formation of siloxane bonds, eliminate ethanol which is obtained in gaseous form at the curing temperature.

The shaped articles produced from the compositions VB 4.2 and VB 4.3 which are used for determining the dielectric properties are introduced into a climate-controlled cabinet with a set climate of 23° C. and 80% relative humidity and their dielectric properties measured after 8, 16 and 32 weeks, wherein the dielectric loss factor and the dielectric constant were determined according to IPC TM 650 2.5.5.13 using a Keysight Agilent E8361A network analyzer at 10 GHz. The following values were obtained:

| | 8 weeks | 16 weeks | 32 weeks |
|---|---|---|---|
| VB 4.2 | D_{f} = 0.0053 | D_{f} = 0.0059 | D_{f} = 0.0066 |
| | Dₖ = 2.90 | Dₖ = 3.04 | Dₖ = 3.19 |
| VB 4.3 | D_{f} = 0.0051 | D_{f} = 0.0058 | D_{f} = 0.0064 |
| | Dₖ = 2.83 | Dₖ = 2.99 | Dₖ = 3.04 |

The shaped articles do not exhibit constant dielectric properties over the test duration. The observed increase in dielectric loss factor is significant. This is a manifestation of both the microporosity within the test specimens caused by the incompatibility of the polyorganosiloxane with the polyphenylene ethers and the lack of hydrolytic stability due to the presence of alkoxy groups under the selected experimental conditions.

In order to demonstrate that this problem can be solved with an inventive preparation and using the inventive procedure an inventive preparation was produced using the polyorganosiloxane of this comparative example 4 analogously to the procedure as described in example 1.

In a departure from the procedure in example 1 this was done using the following substances in the following amounts:

Demineralized water initial charge: 1198.8 g

Vinyldimethylchlorosilane: 90 g (0.75 mol)

Dimethyldichlorosilane: 129 g (1.0 mol)

Phenyltrichlorosilane: 317 g (1.5 mol)

Toluene: 280 g

PPE (X): 138 g

Devolatilization from the solvent takes 1.5 hours.

The obtained product has the following analytical properties:

No alkoxy groups are present. The following molecular weights were determined by SEC (eluent toluene): Mw=3364 g/mol, Mn=1564 g/mol, polydispersity PD=2.15.

According to ²⁹Si NMR the molar composition of the silicon-containing proportion of the preparation is:

Me₂Si(Vi)O_{1/2}: 23.16%

Me₂Si(OR)O_{1/2}: 1.93%

Me₂SiO_{2/2}: 28.54%

PhSi(OR)₂O_{1/2}: 3.92%

PhSi(OR)O_{2/2}: 11.09%

PhSiO_{3/2}: 31.36%

In this case the radical R represents either hydrogen or the polyphenylene ether radical that results from the polyphenylene ether (X) by abstraction of the phenolic H atom and addition reaction onto a silicon atom. According to ¹H NMR, 1.54% by weight of silanol groups are present.

Evaluation of the ¹H-NMR spectrum reveals that the mixture contains 27.6 mol % of the polyphenylene ether of formula (X), wherein the intensity of the phenolic OH signal makes it possible to determine that 5.8% of the polyphenylene ether amount present (27.6 mol % assumed as 100%, of which 5.8% is calculated) is silicon-bonded, i.e. 1.6 mol %

Compositions VB 4.5 and VB 4.6 are produced from the reaction product (=preparation VB 4.4) in the same way as described in example 1.

All obtained compositions are brown and, in contrast to the compositions VB 4.2 and VB 4.3, clear in thin layers and completely homogeneous according to TEM analysis.

DSC gives the following values for the glass transition temperatures of the three cured compositions:

4.1: 115° C.

4.2: 137° C.

4.3: 162° C.

The dielectric loss factor and the dielectric constant of the three cured compositions are determined according to IPC TM 650 2.5.5.13 using a Keysight Agilent E8361A network analyzer. This gives the following values:

| Material | D_{f} (10 GHz) | Dₖ (10 GHz) |
|---|---|---|
| Preparation VB 4.4 | 0.0043 | 2.81 |
| Preparation VB 4.5 | 0.0038 | 2.74 |
| Preparation VB 4.6 | 0.0035 | 2.69 |

The shaped articles produced for determining the dielectric properties are introduced into a climate-controlled cabinet with a set climate of 23° C. and 80% relative humidity and their dielectric properties measured after 8, 16 and 32 weeks, wherein the dielectric loss factor and the dielectric constant were determined according to IPC TM 650 2.5.5.13 using a Keysight Agilent E8361A network analyzer at 10 GHz. The following values were obtained:

| | 8 weeks | 16 weeks | 32 weeks |
|---|---|---|---|
| VB 4.4 | D_{f} = 0.0042 | D_{f} = 0.0044 | D_{f} = 0.0043 |
| | Dₖ = 2.81 | Dₖ = 2.80 | Dₖ = 2.81 |
| VB 4.5 | D_{f} = 0.0038 | D_{f} = 0.0039 | D_{f} = 0.0038 |
| | Dₖ = 2.72 | Dₖ = 2.73 | Dₖ = 2.73 |
| VB 4.6 | D_{f} = 0.0035 | D_{f} = 0.0035 | D_{f} = 0.0035 |
| | Dₖ = 2.69 | Dₖ = 2.70 | Dₖ = 2.70 |

While the shaped articles VB 4.4, VB 4.5 and VB 4.6 produced according to the inventive example 1 exhibit constant dielectric properties over the test duration, the dielectric properties of the shaped articles VB 4.2 and VB 4.3 comprising a polyorganosiloxane according to production example 3 from US 2018/0220350 vary towards higher values. The increase in dielectric loss factor is significant. This is a manifestation of the lack of hydrolytic stability and the lack of compatibility under the selected conditions.

### Comparative Example 5

According to the procedure in production example 2 of US2020/028575 vinylmethyldichlorosilane and the polyphenylene ether of formula (X), which is within the claimed scope of US 2020/028575, are reacted and subsequently a shaped article is produced according to the procedure of use example 3 in US 2020/028575.

The following dielectric properties were determined on the shaped article:

D_{f} (10 GHz according to IPC TM 650 2.5.5.13): 0.0051

Dₖ (10 GHz according to IPC TM 650 2.5.5.13): 2.30

The divergences relative to US 2020/028575 result from the different measurement frequency. In US 2020/028575 the measurement frequency is 1 GHZ. Taking this difference into account, the results are in good agreement and the replication of the experiments described in US 2020/028575 is successful.

The procedure according to use example 3 of US 2020/028575 is used to produce a shaped article from the inventive preparation 1.1 according to example 1 of the present invention. The dielectric properties thereof correspond to the values tabulated in example 1.

The two shaped articles are introduced into a climate-controlled cabinet with a set climate of 23° C. and 80% relative humidity and their dielectric properties measured after 8, 16 and 32 weeks, wherein the dielectric loss factor and the dielectric constant were determined according to IPC TM 650 2.5.5.13 using a Keysight Agilent E8361A network analyzer at 10 GHz. The following values were obtained:

| | 8 weeks | 16 weeks | 32 weeks |
|---|---|---|---|
| Shaped article | D_{f} = 0.0051 | D_{f} = 0.0058 | D_{f} = 0.0068 |
| according to | Dₖ = 2.30 | Dₖ = 2.47 | Dₖ = 2.49 |
| comparative example 5 | | | |
| (US 2020/028575) | | | |
| Shaped body according | D_{f} = 0.0043 | D_{f} = 0.0042 | D_{f} = 0.0043 |
| to inventive example 1 | Dₖ = 2.83 | Dₖ = 2.89 | Dₖ = 2.84 |

While the shaped body according to the inventive example exhibits constant dielectric properties over the test duration the dielectric properties of the shaped article according to US 2020/028575 vary towards higher values. The increase in dielectric loss factor is significant. This is a manifestation of the lack of hydrolytic stability under the selected conditions.

1-10. (canceled)

11. A process for producing compositions, wherein
a) compounds selected from hydroxy-terminated homopolymeric or copolymeric polyphenylene ethers and phenols are reacted with
b) chlorosilane of formula (I) alone or in admixture with disiloxane of formula (IV)
R¹ₐR²_{b}SiCl_{4-a-b} (I),
[R¹_{(3-b)}R²_{b}Si]₂O (IV)
in the presence of water and solvent,
wherein
R¹ represents identical or different, optionally heteroatom-substituted aliphatic, cycloaliphatic or aromatic C1-C12 radicals, wherein the proportion of chlorosilanes of formula (I) having an aromatic radical is to be selected such that in the polyorganosiloxane formed from the chlorosilane of formula (I) or a mixture of different chlorosilanes of formula (I) the proportion of aromatic substituents, based on 100 mol % of all radicals silicon-bonded by an Si—C bond, is at least 10 mol %,
R² represents a hydrogen atom, a mono- or polyunsaturated C2-C8 hydrocarbon radical which may additionally contain further acid-stable functional groups,
a=1, 2 or 3,
b=0, 1, 2 or 3,
with the proviso that a +b≤3,
wherein in a mixture of different chlorosilanes of formula (I) at least one chlorosilane of formula (I) for which 4−a−b=3 must be present and the relative proportion of the chlorosilane of formula (I) for which 4−a−b=3 in the mixture with other chlorosilanes is at least 20 mol %,
wherein the disiloxanes of formula (IV) have a symmetrical structure, so that the radicals R¹ and R² on both silicon atoms each have the same definition, with the proviso that at most 60 mol % of disiloxanes of formula (IV) are employed based on the employed amount of chlorosilanes as 100 mol %.

12. A composition producible from
a) compounds selected from hydroxy-terminated homopolymeric or copolymeric polyphenylene ethers and phenols with
b) chlorosilane of formula (I) alone or in admixture with disiloxane of formula (IV)
R¹ₐR²_{b}SiCl_{4-a-b} (I),
[R¹_{(3-b)}R²_{b}Si]₂O (IV)
in the presence of water and solvent,
wherein
R¹ represents identical or different, optionally heteroatom-substituted aliphatic, cycloaliphatic or aromatic C1-C12 radicals, wherein the proportion of chlorosilanes of formula (I) having an aromatic radical is to be selected such that in the polyorganosiloxane formed from the chlorosilane of formula (I) or a mixture of different chlorosilanes of formula (I) the proportion of aromatic substituents, based on 100 mol % of all radicals silicon-bonded by an Si—C bond, is at least 10 mol %,
R² represents a hydrogen atom, a mono- or polyunsaturated C2-C8 hydrocarbon radical which may additionally contain further acid-stable functional groups,
a=1, 2 or 3,
b=0, 1, 2 or 3,
with the proviso that a+b≤3,
wherein in a mixture of different chlorosilanes of formula (I) at least one chlorosilane of formula (I) for which 4−a−b=3 must be present and the relative proportion of the chlorosilane of formula (I) for which 4−a−b=3 in the mixture with other chlorosilanes is at least 20 mol %,
wherein the disiloxanes of formula (IV) have a symmetrical structure, so that the radicals R¹ and R² on both silicon atoms each have the same definition, with the proviso that at most 60 mol % of disiloxanes of formula (IV) are employed based on the employed amount of chlorosilanes as 100 mol %.

13. The process as claimed in claim 11, wherein the radical R¹ represents unsubstituted hydrocarbon radicals having 1 to 12 carbon atoms.

14. The composition as claimed in claim 12, wherein the radical R¹ represents unsubstituted hydrocarbon radicals having 1 to 12 carbon atoms.

15. The process as claimed in claim 11, wherein the molar ratio of all Si—C-bonded aromatic and aliphatic radicals R¹ expressed as the fraction assumes values of 1.0 to 0.05.
$$\frac{Molzahl aromatische Reste {R}^{1}}{Molzahl aromatische Reste {R}^{1} + Molzahl aliphatische Reste {R}^{1}}$$

16. The composition as claimed in claim 12, wherein the molar ratio of all Si—C-bonded aromatic and aliphatic radicals R¹ expressed as the fraction assumes values of 1.0 to 0.05.
$$\frac{Molzahl aromatische Reste {R}^{1}}{Molzahl aromatische Reste {R}^{1} + Molzahl aliphatische Reste {R}^{1}}$$

17. The process as claimed in claim 11, wherein the polyphenylene ethers have the formula (VII), 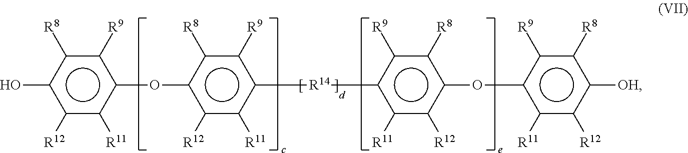
in which
R⁸, R⁹, R¹¹ and R¹² independently of one another represent a hydrogen radical, a hydrocarbon group or a heteroatom-substituted hydrocarbon group with the proviso that at least one of the radicals R⁸, R⁹ R¹¹ and R¹² always represents a hydrogen radical, the radical R¹⁴ represents a chemical bond or a divalent, optionally substituted arylene radical of the form (—C₆R¹⁵₄—), wherein R¹⁵ independently thereof may have the same definition as the radicals R⁸, R⁹, R¹¹ or R¹², or an alkylene radical of the form —CR¹⁶₂—, wherein R¹⁶ independently of R¹⁵ may have the same definitions as R¹⁵, a divalent glycol radical of the form —[(OCH₂)₂O]_{f}— or —[(OCH₂CH(CH₃)₂)O]g—, wherein f and g may each independently of one another represent integers in the value of in each case 1 to 50 inclusive, a divalent silyloxy radical of the form —Si(R¹⁷)₂O_{2/2}—, a divalent siloxane radical of the form —[(CH₂)₃Si—[O—Si(R¹⁸)₂]ₕO—Si(CH₂)₃—, a divalent silyl radical of the form —Si(R¹⁹)₂—, wherein R¹⁷, R¹⁸ and R¹⁹ independently of one another and independently of R¹⁵ may have the same definitions as R¹⁵, and h is an integer having a value of in each case 0 to 500 inclusive,
c, d and e are integers, wherein
c is an integer having a value of in each case 2 to 50 inclusive,
d is an integer having a value of in each case 1 to 10 inclusive and
e is an integer having a value of in each case 2 to 50 inclusive.

18. The composition as claimed in claim 12, wherein the polyphenylene ethers have the formula (VII), 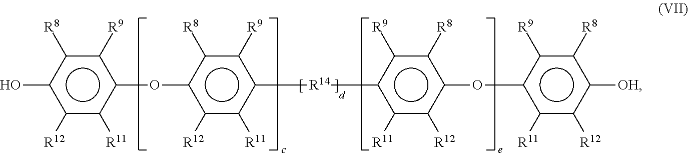
in which
R⁸, R⁹, R¹¹ and R¹² independently of one another represent a hydrogen radical, a hydrocarbon group or a heteroatom-substituted hydrocarbon group with the proviso that at least one of the radicals R⁸, R⁹ R¹¹ and R¹² always represents a hydrogen radical, the radical R¹⁴ represents a chemical bond or a divalent, optionally substituted arylene radical of the form (—C6R¹⁵₄—), wherein R¹⁵ independently thereof may have the same definition as the radicals R⁸, R⁹, R¹¹ or R¹², or an alkylene radical of the form —CR¹⁶₂—, wherein R¹⁶ independently of R¹⁵ may have the same definitions as R¹⁵, a divalent glycol radical of the form —[(OCH₂)₂O]_{f}— or —[(OCH₂CH(CH₃)₂)O]_{g}—, wherein f and g may each independently of one another represent integers in the value of in each case 1 to 50 inclusive, a divalent silyloxy radical of the form —Si(R¹⁷)_{202/2}—, a divalent siloxane radical of the form —[(CH₂)₃Si—[O—Si(R¹⁸)₂]ₕO—Si(CH₂)₃—, a divalent silyl radical of the form —Si(R¹⁹)₂—, wherein R¹⁷, R¹⁸ and R¹⁹ independently of one another and independently of R¹⁵ may have the same definitions as R¹⁵, and h is an integer having a value of in each case 0 to 500 inclusive,
c, d and e are integers, wherein
c is an integer having a value of in each case 2 to 50 inclusive,
d is an integer having a value of in each case 1 to 10 inclusive and
e is an integer having a value of in each case 2 to 50 inclusive.

19. The process as claimed in claim 11, wherein the phenols have the formula (V), 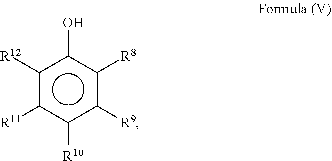
in which R⁸, R⁹, R¹⁰, R¹¹ and R¹² independently of one another represent a hydrogen radical, a hydrocarbon group or a heteroatom-substituted hydrocarbon group with the proviso that at least one of the radicals R⁸, R⁹, R¹⁰, R¹¹ and R¹² always represents a hydrogen radical, wherein the radical R¹⁰ preferably represents a hydrogen radical.

20. The composition as claimed in claim 12, wherein the phenols have the formula (V), 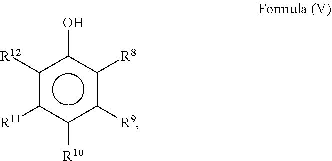
in which R⁸, R⁹, R¹⁰, R¹¹ and R¹² independently of one another represent a hydrogen radical, a hydrocarbon group or a heteroatom-substituted hydrocarbon group with the proviso that at least one of the radicals R⁸, R⁹, R¹⁰, R¹¹ and R¹² always represents a hydrogen radical, wherein the radical R¹⁰ preferably represents a hydrogen radical.

21. A polyorganosiloxane comprising polyphenylene ether radicals producible by the process as claimed in claim 11.

22. The use of the composition as claimed in claim 12 for use as binders for production of shaped articles having constant dielectric properties.

23. The use as claimed in claim 22, wherein the shaped articles are fiber composites.

24. The use as claimed in claim 22, wherein the fiber composites are copper-clad laminates made of glass fiber composites for further production of printed circuit boards.
